(19) United States
(12) Patent Application Publication
(10) Pub. No.: US 2026/0068121 A1
(43) Pub. Date: Mar. 5, 2026

(54) SEMICONDUCTOR DEVICES

(71) Applicant: Samsung Electronics Co., Ltd., Suwon-si (KR)

(72) Inventors: Eunsuk Jang, Suwon-si (KR); Jinwoo Han, Suwon-si (KR); Woochul Kim, Suwon-si (KR); Hyebin Kim, Suwon-si (KR); Jihoon Choi, Suwon-si (KR)

(21) Appl. No.: 19/095,491

(22) Filed: Mar. 31, 2025

(30) Foreign Application Priority Data
Aug. 27, 2024 (KR) 10-2024-0115173

(51) Int. Cl. H10B 12/00

(52) U.S. Cl. CPC H10B 12/30; H10B 12/03; H10B 12/05

(57) ABSTRACT

The semiconductor device includes a plurality of channels on a substrate and spaced apart from each other along a first direction parallel to an upper surface of the substrate and a second direction perpendicular to the upper surface of the substrate; a plurality of gate structures, each extending in the first direction and at least partially surrounding portions of a first subset of the plurality of channels arranged in the first direction, and spaced apart from each other along the second direction; a plurality of bit lines; a capping layer on upper surfaces and upper sidewalls of the plurality of bit lines; and an air spacer in a space between the channels, the plurality of gate structures and the plurality of bit lines, and the space being located between the upper surface of the substrate and a lower surface of the capping layer.

### CROSS-REFERENCE TO RELATED APPLICATION

This application claims priority under 35 U.S.C. § 119 to Korean Patent Application No. 10-2024-0115173, filed on Aug. 27, 2024, in the Korean Intellectual Property Office (KIPO), the disclosure of which is incorporated by reference herein in its entirety.

### TECHNICAL FIELD

Example embodiments of the inventive concept relate to a semiconductor device. More particularly, example embodiments of the inventive concept relate to a three-dimensional (3D) memory device.

### BACKGROUND

A DRAM device includes word lines, bit lines, channels and capacitors. To increase the integration degree of the DRAM device, the word lines, the bit lines, the channels and the capacitors are needed to be efficiently arranged.

### SUMMARY

Example embodiments of the inventive concept provide a semiconductor device having enhanced electrical characteristics.

According to example embodiments of the inventive concept, there is provided a semiconductor device. The semiconductor device may include a plurality of channels on a substrate and spaced apart from each other along a first direction substantially parallel to an upper surface of the substrate and a second direction substantially perpendicular to the upper surface of the substrate; a plurality of gate structures, each extending in the first direction and at least partially surrounding portions of a first subset of the plurality of channels arranged in the first direction, and spaced apart from each other along the second direction; a plurality of bit lines, each extending in the second direction and contacting sidewalls of a second subset of the plurality of channels arranged in the second direction, and spaced apart from each other along the first direction; a capping layer on upper surfaces and upper sidewalls of the plurality of bit lines; a capacitor electrically connected to the plurality of channels; and an air spacer in a space between the plurality of channels, the plurality of gate structures and the plurality of bit lines, and the space being between the upper surface of the substrate and a lower surface of the capping layer.

According to example embodiments of the inventive concept, there is provided a semiconductor device. The semiconductor device may include a plurality of channels on a substrate, each extending in a first direction substantially parallel to an upper surface of the substrate, and spaced apart from each other along a second direction and a third direction, the second direction substantially parallel to the upper surface of the substrate and crossing the first direction and the third direction substantially perpendicular to the upper surface of the substrate; a plurality of gate structures, each at least partially surrounding portions of a first subset of the plurality of channels arranged in the second direction, extending in the second direction, and spaced apart from each other in the third direction; a plurality of bit lines, each contacting first sidewalls in the first direction of a second subset of plurality of channels arranged along the third direction, each extending in the third direction, and spaced apart from each other in the second direction; an insulating interlayer contacting upper surfaces of the plurality of bit lines; capping patterns, each extending through the insulating interlayer, and spaced apart from each other in the second direction, wherein lower surfaces of the capping patterns are higher than a lower surface of the insulating interlayer and the upper surface of the substrate provides a base reference plane; a capacitor electrically connected to second sidewalls in the first direction of the plurality of channels; and an air spacer in a space between the plurality of channels, the plurality of gate structures and the plurality of bit lines, and the space being located between lower surfaces of the insulating interlayer and the capping patterns and the upper surface of the substrate.

According to example embodiments of the inventive concept, there is provided a semiconductor device. The semiconductor device may include a plurality of channels on a substrate, each extending in a first direction substantially parallel to an upper surface of the substrate, and spaced apart from each other along a second direction and a third direction, the second direction substantially parallel to the upper surface of the substrate and crossing the first direction and the third direction substantially perpendicular to the upper surface of the substrate; a plurality of gate structures, each at least partially surrounding portions of a subset of the plurality of channels arranged in the second direction, extending in the second direction, and spaced apart from each other in the third direction; a division structure between neighboring ones of the plurality of gate structures in the third direction; a plurality of bit lines, each contacting a first sidewall in the first direction of each of the channels arranged along the third direction, each extending in the third direction, and spaced apart from each other in the second direction; a liner on the upper surface of the substrate, surfaces of the gate structures, and a sidewall of the division structure; an insulating layer on upper surfaces of the bit lines and an uppermost surface of the liner; a capacitor electrically connected to a second sidewall in the first direction of each of the plurality of channels; and an air spacer in a space between a surface of the liner and a lower surface of the insulating layer.

The semiconductor device in accordance with example embodiments, an air spacer including air with a low dielectric constant may be between a gate structure and a contact portion of a channel. As a result, parasitic coupling capacitance between the gate structure and the contact portion of the channel may be reduced, thereby improving the reliability of the semiconductor device.

### BRIEF DESCRIPTION OF DRAWINGS

FIGS. 1 to 6 are a plan view, a horizontal cross-sectional view and vertical cross-sectional views illustrating a semiconductor device in accordance with example embodiments.

FIGS. 7 to 46 are horizontal cross-sectional views, vertical cross-sectional views and perspective views illustrating a method of manufacturing a semiconductor device in accordance with example embodiments.

FIGS. 47 to 56 are vertical cross-sectional views and horizontal cross-sectional views illustrating a semiconductor device in accordance with example embodiments.

FIGS. 57 to 60 are perspective views illustrating a method of manufacturing a semiconductor device in accordance with example embodiments.

FIG. 61 is a horizontal cross-sectional view illustrating a semiconductor device in accordance with example embodiments.

FIGS. 62 to 64 are horizontal cross-sectional views illustrating a method of manufacturing a semiconductor device in accordance with example embodiments.

FIG. 65 is a vertical cross-sectional view illustrating a semiconductor device in accordance with example embodiments.

FIG. 66 is a vertical cross-sectional view illustrating a semiconductor device in accordance with example embodiments.

### DETAILED DESCRIPTION OF THE EMBODIMENTS

The above and other aspects and features of the semiconductor devices and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably for each material, layer, region, electrode, pad, pattern, structure or process respectively.

Two directions among horizontal directions that are substantially parallel to an upper surface of the substrate, which intersect each other, may be referred to as first and second directions D1 and D2, respectively, and a direction substantially vertical to the upper surface of the substrate may be referred to as a third direction D3. In example embodiments, the first and second directions D1 and D2 may be substantially perpendicular to each other. Each of the first to third directions D1, D2 and D3 may include not only a direction shown in the drawings but also a direction opposite thereto.

The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids or other spaces throughout. The term “exposed,” may be used to describe relationships between elements and/or certain intermediate processes in fabricating a completed semiconductor device, but may not necessarily require exposure of the particular region, layer, structure or other element in the context of the completed device.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

It is noted that aspects described with respect to one embodiment may be incorporated in different embodiments although not specifically described relative thereto. That is, all embodiments and/or features of any embodiments can be combined in any way and/or combination.

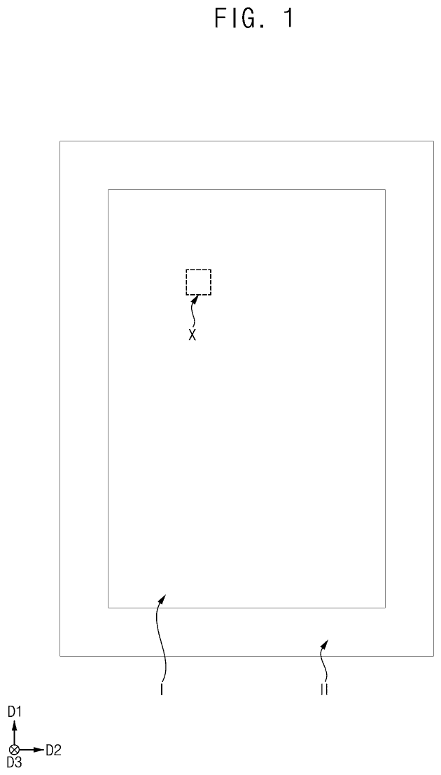

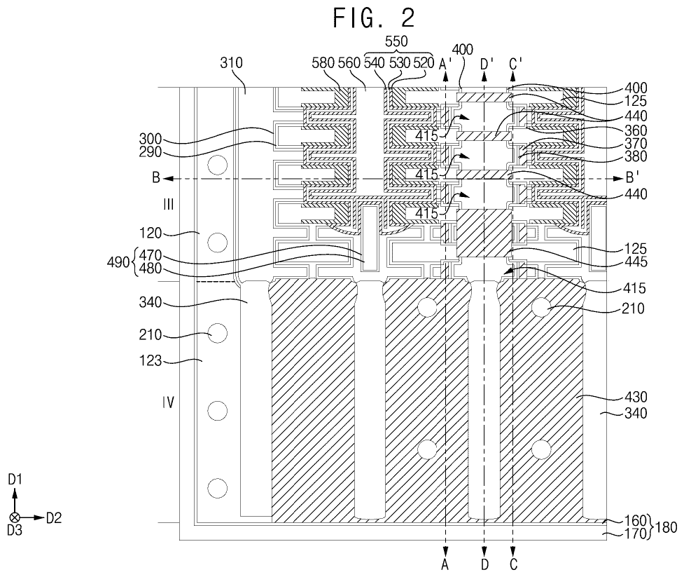

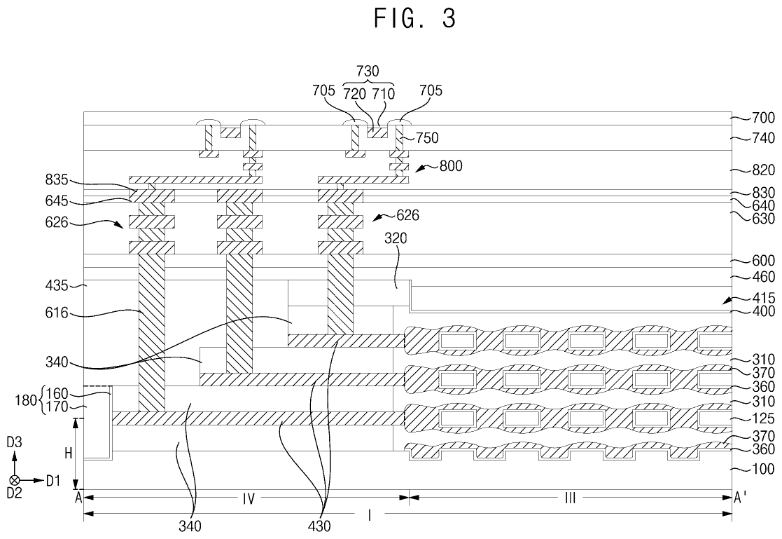

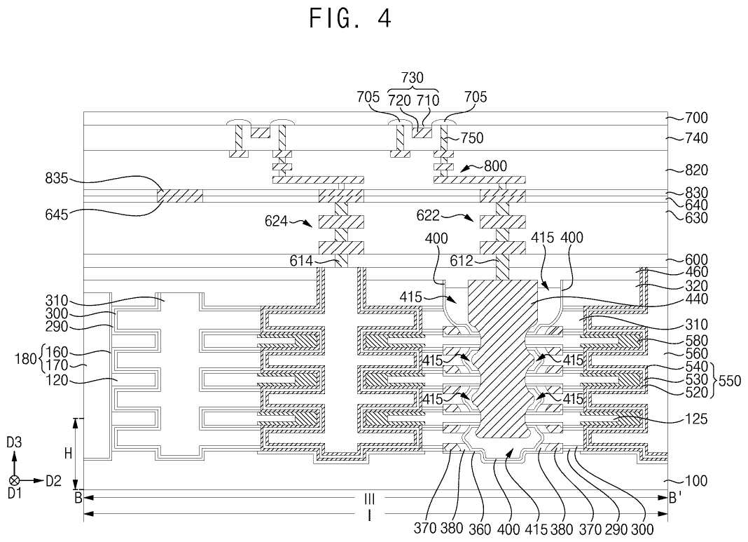

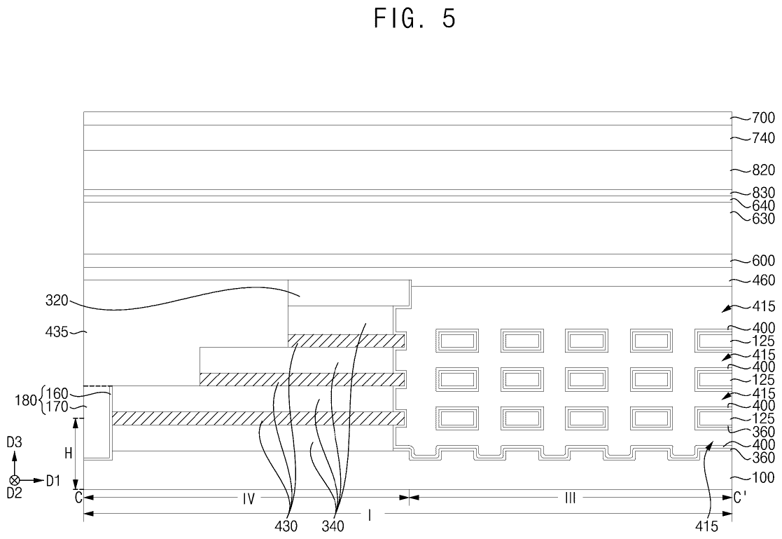

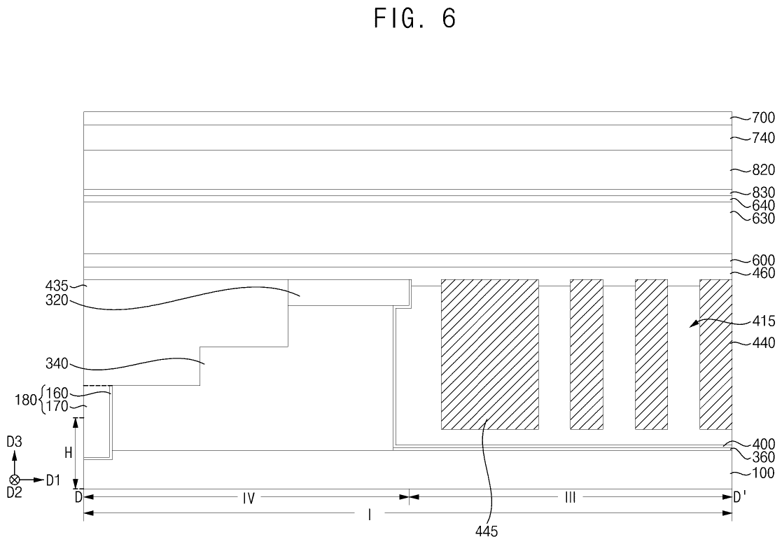

FIGS. 1 to 6 are a plan view, a horizontal cross-sectional view and vertical cross-sectional views illustrating a semiconductor device in accordance with example embodiments. Particularly, FIG. 1 is the plan view, FIG. 2 is the horizontal cross-sectional view, FIGS. 3 to 6 are the vertical cross-sectional views.

FIG. 1 is a plan view illustrating regions included in the semiconductor device. FIG. 2 is a horizontal cross-sectional view taken at heights H of FIGS. 3 to 6 in region X of FIG. 1. FIGS. 3 to 6 are vertical cross-sectional views respectively taken along lines A-A′, B-B′, C-C′ and D-D′ of FIG. 2 in region X of FIG. 1.

Referring to FIGS. 1 to 6, the semiconductor device may include first and second regions I and II.

In example embodiments, the first region I may be a memory cell region in which memory cells are formed, and the second region II may be a peripheral circuit region in which circuit patterns for applying electrical signals to the memory cells are formed. The first region I may include memory cell block regions each of which may include memory cells, and the memory cell block regions may be arranged in each of the first and second directions D1 and D2 and may be separated from each other by a first division structure 180.

The first division structure 180 may contact an upper surface of the first region I of the first substrate 100 and may have a lattice shape in a plan view. In an example embodiment, the first division structure 180 may include a first division pattern 160 and a second division pattern 170 covering a sidewall and a lower surface of the first division pattern 160. The first division pattern 160 may include an insulating nitride, e.g., silicon nitride, and the second division pattern 170 may include an oxide, e.g., silicon oxide.

Each of the memory cell block regions may include third and fourth regions III and IV. The third region III may be a memory cell array region in which a memory cell array including the memory cells is formed, and the fourth region IV may be a pad region or an extension region in which contact plugs for transferring electrical signals to the memory cell array or conductive pads contacting the contact plugs are formed.

In example embodiments, the fourth region IV may be disposed at one side or opposite sides in the first direction D1 of the third region III. FIG. 2 shows a portion of the memory cell block region, that is, a portion of each of the third and fourth regions III and IV.

In the specification, each of the first to fourth regions I, II, III and IV may be defined in an inside of the first substrate 100 and/or the second substrate 700 on which the semiconductor device is formed or may also be defined in a space over and under the first substrate 100 and/or the second substrate 700.

In example embodiments, the semiconductor device may have a periphery over cell (POC) structure or a cell over periphery (COP) structure. Thus, some of the circuit patterns may be disposed not only in the peripheral circuit region but also over or under the memory cells in the memory cell region. FIGS. 1 to 6 show that some of the circuit patterns are disposed over the memory cells so that the semiconductor device has a POC structure.

In some cases, an upper portion of the memory cell region, that is, a region in which some of the circuit patterns are formed may be referred to as a core region, and a lower portion of the memory cell region, that is, a region in which the memory cells are formed may be referred to as a memory cell region.

As the semiconductor device has a POC structure, the peripheral circuit region may have upper and lower portions. Some of the circuit patterns may be disposed at an upper portion of the peripheral circuit region, and others of the circuit patterns may be disposed at a lower portion of the peripheral circuit region.

The memory cell region and the core region may be differentiated from each other by a bonding layer structure including first and second bonding layers 640 and 830, and the upper and lower portions of the peripheral circuit region may also be differentiated from each other by the bonding layer structure including the first and second bonding layers 640 and 830.

The semiconductor device may include a channel 125, a first gate structure, a bit line 440, a liner 400, an air spacer 415, a capping layer 460, a capacitor structure, a conductive pad 430, first to third contact plugs 612, 614 and 616 and first to third wiring structures 622, 624 and 626 on the first region I of the first substrate 100.

Additionally, the semiconductor device may include a dummy bit line 445, a blocking structure 490, a first division structure 180, a third division structure, a third division pattern 200, a support pattern 210, a semiconductor layer 120, a semiconductor pattern 123, a second mask 320, an eighth division pattern 340 and second to fourth insulating interlayers 435, 600 and 630 on the first region I of the first substrate 100.

Furthermore, the semiconductor device may include a transistor, a fourth contact plug 750 and a fourth wiring structure 800 under the first region I of the second substrate 700.

The semiconductor device may further include fifth and sixth insulating interlayers 740 and 820 under the second substrate 700, and the bonding layer structure may be disposed between the fourth insulating interlayer 630 on the first substrate 100 and the sixth insulating interlayer 820 under the second substrate 700.

Each of the first and second substrates 100 and 700 may include a semiconductor material, e.g., silicon, germanium, silicon-germanium, etc., or a III-V group compound semiconductor, such as GaP, GaAs, GaSb, etc. In an example embodiment, each of the first and second substrates 100 and 700 may be a silicon-on-insulator (SOI) substrate or a germanium-on-insulator (GOI) substrate.

The channel 125 may extend a predetermined length in the second direction D2 on the third region III of the first substrate 100, and a plurality of channels 125 may be spaced apart from each other in the first direction D1 to form a channel row at a height from the upper surface of the first substrate 100. In example embodiments, a plurality of channel rows may be spaced apart from each other in the second direction D2 to form a channel array. Additionally, a plurality of channels 125 may be spaced apart from each other in the third direction D3, so that a plurality of channel rows may be spaced apart from each other in the third direction D3 and a plurality of channel arrays may be spaced apart from each other in the third direction D3.

The semiconductor layer 120 may extend in the first direction D1 at each of opposite sides in the second direction D2 on the third region III of the first substrate 100. In example embodiments, the semiconductor layer 120 and the channel 125 may be disposed at substantially the same height from the upper surface of the first substrate 100.

The semiconductor pattern 123 may extend in the first direction D1 at each of opposite sides in the second direction D2 on the fourth region IV of the first substrate 100. The semiconductor pattern 123 may contact and be connected to the semiconductor layer 120.

Each of the channels 125, the semiconductor layer 120 and the semiconductor pattern 123 may include substantially the same material, e.g., a semiconductor material such as silicon.

A portion of the channel 125 contacting the bit line 440 and further including, for example, n-type impurities may be referred to as a contact portion.

The first gate structure may surround a portion of the channel 125, and may include a first gate electrode 370, a first gate insulation pattern 360 and a first gate mask 380. In example embodiments, the first gate structure may extend in the first direction D1 and surround portions of the channels 125 in each of the channel rows on the third region III of the first substrate 100, and a plurality of first gate structures may be spaced apart from each other in the second direction D2. Each of the first gate structures may serve as a word line of the semiconductor device.

Hereinafter, for convenience of explanation, the portion of the channel 125 surrounded by the first gate electrode 370 included in the first gate structure may be referred to as a central portion, and portions extending along the second direction D2 from opposite sides of the central portion of the channel 125 may be respectively referred to as a first extension portion and a second extension portion. As will be described later, the first extension portion of the channel 125 may contact the bit line 440, and the second extension portion of the channel 125 may contact the first capacitor electrode 520 of the capacitor structure. Meanwhile, the first extension portions or the second extension portions of neighboring ones of the channels 125 in the second direction D2 may face each other in the second direction D2.

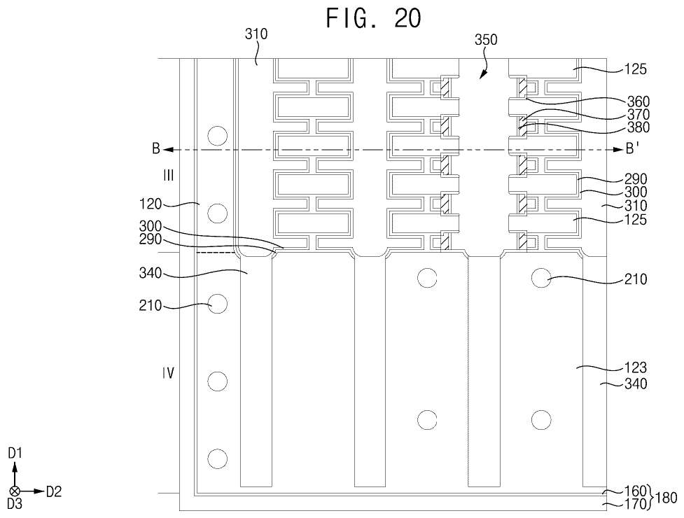

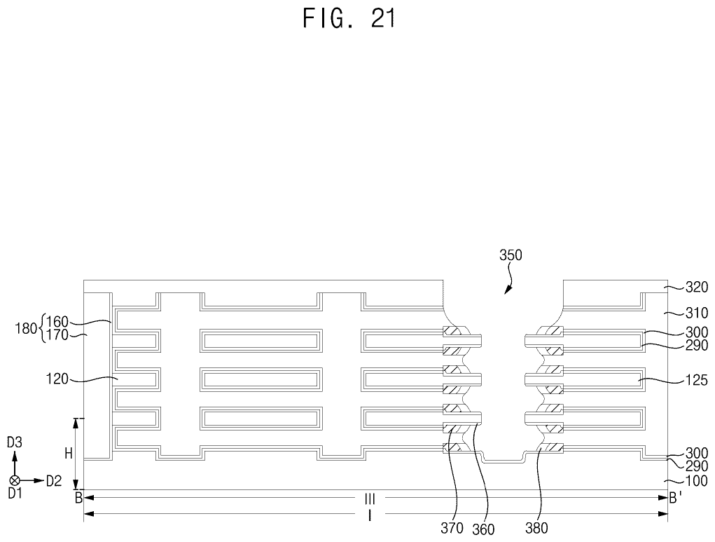

Referring to FIGS. 20 and 21 together with FIGS. 1 to 6, the first gate insulation pattern 360 may cover the upper surface of the first substrate 100 exposed by the seventh opening 350, upper and lower surfaces and opposite sidewalls in the first direction D1 of the central portion of the channel 125, and upper and lower surfaces and opposite sidewalls in the first direction D1 of the first extension portion of the channel 125. The first gate insulation pattern 360 may include an oxide, e.g., silicon oxide.

The first gate electrode 370 may cover lower and upper surfaces and opposite sidewalls in the first direction D1 of a portion of the first gate insulation pattern 360. In example embodiments, the first gate electrode 370 may extend in the first direction D1 and may cover the portions of ones of the first gate insulation patterns 360 disposed in the first direction D1. The first gate electrode 370 may include a conductive material, e.g., a metal, a metal nitride, a metal silicide, etc.

The first gate mask 380 may cover lower and upper surfaces and opposite sidewalls in the first direction D1 of a portion of the first gate insulation pattern 360, and may contact a sidewall in the second direction D2 of the first gate electrode 370. The first gate mask 380 may include an insulating nitride, e.g., silicon nitride.

The conductive pad 430 may extend in the first direction D1 on the fourth region IV of the first substrate 100, and a plurality of conductive pads 430 may be spaced apart from each other in the second direction D2. In example embodiments, at least a portion of the conductive pad 430 may be disposed at substantially the same height as the first gate electrode 370 and may contact a sidewall in the first direction D1 of the first gate electrode 370 to be electrically connected thereto. In example embodiments, the conductive pad 430 may overlap the first gate structure and the channel 125 in the first direction D1.

In example embodiments, a plurality of conductive pads 430 may be spaced apart from each other in the third direction D3, and lengths in the first direction D1 of the conductive pads 430 may decrease from a lowermost one to an uppermost one thereof in a stepwise manner. Thus, the conductive pads 430 disposed in the third direction D3 may form a staircase structure.

The conductive pad 430 may include a conductive material, e.g., a metal, a metal nitride, a metal silicide, doped polysilicon, etc.

In example embodiments, the third division structure may include first and second insulation patterns 290 and 300 and a seventh division pattern 310.

The third division structure may fill spaces between the first gate structures stacked in the third direction D3, between the semiconductor layers 120 stacked in the third direction D3, and between the second mask 320 and the first gate structures, the channels 125 and the semiconductor layers 120 at a uppermost layer.

The first and second insulation patterns 290 and 300 may be sequentially stacked on a surface of each of the channels 125, and the seventh division pattern 310 may be disposed on the second insulation pattern 300 and fill other portions of the spaces.

The first insulation pattern 290 and the seventh division pattern 310 may include an oxide, e.g., silicon oxide, and the second insulation pattern 300 may include an insulating nitride, e.g., silicon nitride.

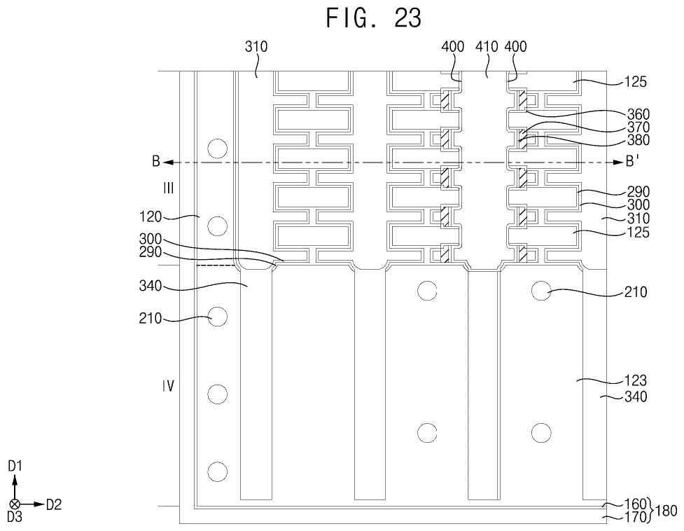

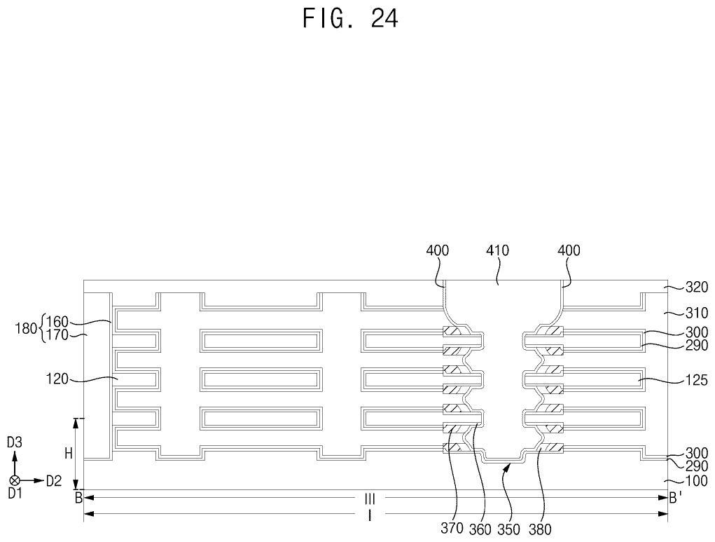

Referring to FIGS. 23 to 25 together with FIGS. 1 to 6, the liner 400 may cover a surface of a portion of the first gate insulation pattern 360 covering the upper surface of the first substrate 100 and the first extension portion of each of the channels 125 exposed by the seventh opening 350, a sidewall in the second direction D2 of the first gate structure, a sidewall in the second direction D2 of a portion of the third division structure disposed between neighboring ones of the first gate structures in the third direction D3, and sidewalls of the second mask 320 in the second direction D2.

The air spacer 415 may be provided in a space defined by a surface of the liner 400 and a lower surface of the capping layer 460. Specifically, the air spacer 415 may include spaces: between the first extension portions of the channels 125 spaced apart from each other in the second and third directions D2 and D3 on the first region I of the first substrate 100; between the bit lines 440 spaced apart from each other in the first direction D1; between the dummy bit line 445 and the eighth division pattern 340 spaced apart from each other in the first direction D1; between lower surfaces of the bit lines 440 and the upper surface of the first substrate 100; between lower surfaces of the first extension portions of each of the channels 125 disposed at lowermost layer and the upper surface of the first substrate 100; and between the first extension portion of each of the channels 125 disposed at the uppermost layer and the lower surface of the capping layer 460

In example embodiments, neighboring ones of the bit lines 440 in the first direction D1, the bit line 440 and the dummy bit line 445 neighboring each other in the first direction D1, and the dummy bit line 445 and the eighth division pattern 340 neighboring each other in the first direction D1 may include portions facing each other with the air spacer 415 therebetween. In example embodiments, the lower surfaces of the bit lines 440 and a lower surface of the dummy bit line 445 may face the upper surface of the first substrate 100 in the third direction D3 with the air spacer 415 therebetween. In example embodiments, the bit line 440 may face the seventh division pattern 310 in the second direction D2 with the air spacer 415 therebetween. In example embodiments, the bit line 440 may face the second mask 320 in the second direction D2 with the air spacer 415 therebetween. In example embodiments, the dummy bit line 445 may face the second mask 320 in the first and second directions D1 and D2 with the air spacer 415 therebetween.

In example embodiments, neighboring ones of the first gate structures in the second direction D2 may include portions facing each other with the air spacer 415 therebetween. In example embodiments, an upper surface of the first gate structure disposed at the uppermost layer may face the lower surface of the capping layer 460 in the third direction D3 with the air spacer 415 therebetween.

In example embodiments, a width in the first direction D1 of the channel 125 may be formed larger than a width in the first direction D1 of the bit line 440, such that neighboring one of the channels 125 in the second direction D2 may include portions facing each other with the air spacer 415 therebetween. In example embodiments, the first extension portions of neighboring ones of the channels 125 in the first direction D1 or the third direction D3 may face each other with the air spacer 415 therebetween. In example embodiments, lower surfaces of each of the channels 125 disposed at the lowermost layer may include portions facing the upper surface of the first substrate 100 in the third direction D3 with the air spacer 415 therebetween. In example embodiments, upper surfaces of each of the channels 125 disposed at the uppermost layer may face the lower surface of the capping layer 460 in the third direction D3 with the air spacer 415 therebetween. In example embodiments, neighboring ones of the channels 125 in the first direction D1 may face the conductive pad 430 with the air spacer 415 therebetween.

In example embodiments, the capping layer 460 may include portions facing the upper surface of the first substrate 100 in the third direction D3 with the air spacer 415 therebetween.

The liner 400 may include an insulating nitride, e.g., silicon nitride, an oxide, e.g., silicon oxide, silicon carbonitride, etc., and the air spacer 415 may include air.

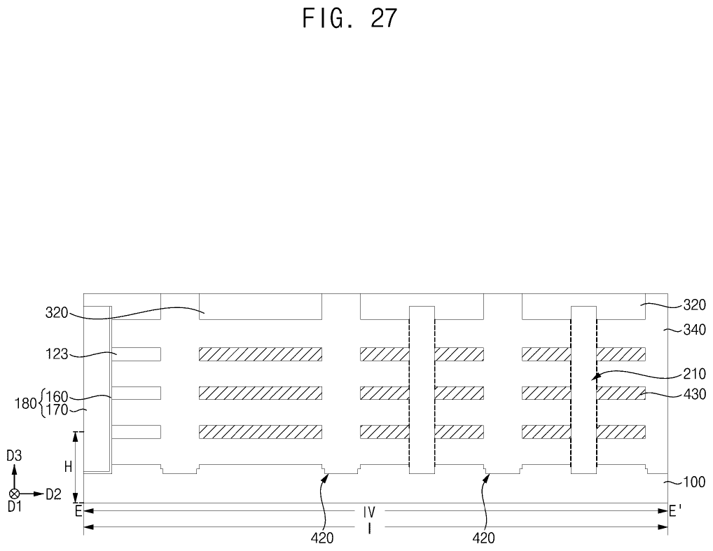

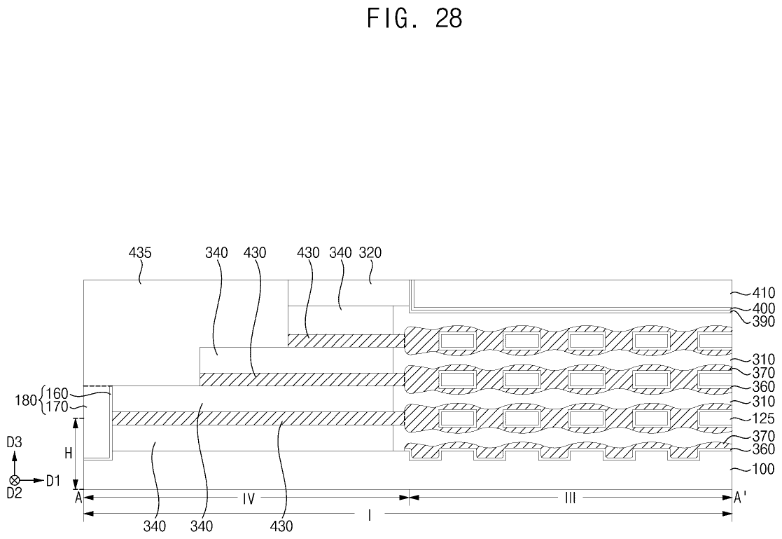

Referring to FIGS. 27 and 28 together with FIGS. 1 to 6, the eighth division pattern 340 may be disposed on the fourth region IV of the first substrate 100, and may fill spaces between conductive pads 430 and between semiconductor patterns 123 that are stacked in the third direction D3, between the upper surface of the first substrate 100 and each of the conductive pad 430 and the semiconductor pattern 123, and between the second mask 320 and each of an uppermost one of the conductive pads 430 and an uppermost one of the semiconductor patterns 123.

Additionally, the eighth division pattern 340 may be disposed between neighboring ones of the conductive pads 430 in the first direction D1 and between the semiconductor patterns 123 and the conductive pads 430 neighboring in the first direction D1 on the fourth region IV of the first substrate 100.

In example embodiments, lengths in the first direction D1 of the eighth division patterns 340 disposed in the third direction D3 may decrease from a lowermost one to an uppermost one in a stepwise manner, and thus a stack structure including the eighth division patterns 340 may be a staircase structure. In example embodiments, one of the eighth division patterns 340 on a corresponding one of the conductive pads 430 may collectively form one step layer, and a sidewall in the first direction D1 of each of the eighth division patterns 340 may be aligned with a sidewall in the first direction D1 of the corresponding one of the conductive pads 430 in the third direction D3.

The eighth division pattern 340 may include an insulating nitride, e.g., silicon nitride.

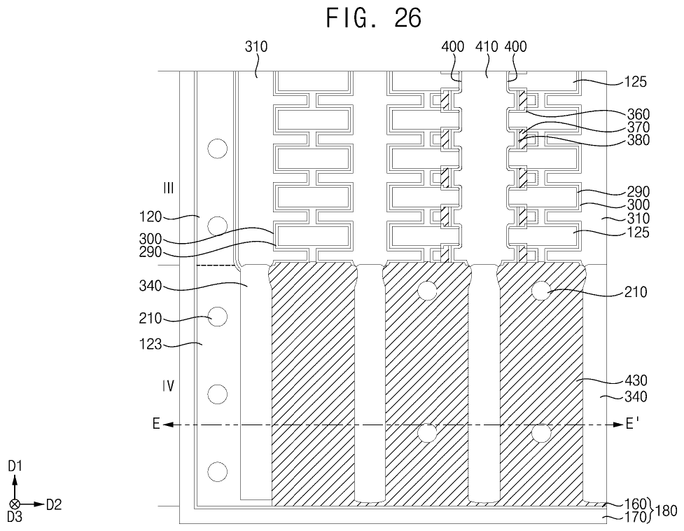

Referring to FIGS. 26 to 28 together with FIGS. 1 to 6, the support pattern 210 may be disposed on the first and second regions I and II of the first substrate 100, and may extend through the semiconductor layers 120, the third division structure, the eighth division pattern 340 and the conductive pads 430 to contact the upper surface of the first substrate 100. A plurality of support patterns 210 may be spaced apart from each other in the first direction D1 at each of opposite sides in the second direction D2 of the third region III of the first substrate 100, and a plurality of support patterns 210 may be spaced apart from each other in each of the first and second directions D1 and D2 on the fourth region IV of the first substrate 100. Additionally, a plurality of support patterns 210 may be spaced apart from each other on an edge portion of the fourth region IV of the first substrate 100.

The support pattern 210 may include an insulating nitride, e.g., silicon nitride, and may be merged with the eighth division pattern 340.

The second mask 320 may be disposed on the third division structure and the eighth division pattern 340 on the first and second regions I and II of the first substrate 100. The second mask 320 may include an insulating nitride, e.g., silicon nitride.

The second insulating interlayer 435 may be disposed on the eighth division pattern 340 on the fourth region IV of the first substrate 100. In example embodiments, an upper surface of the second insulating interlayer 435 may be substantially coplanar with an upper surface of the second mask 320. The second insulating interlayer 435 may include an oxide, e.g., silicon oxide.

The bit line 440 may extend in the third direction D3 partially through the air spacer 415 extending in the first direction D1 on the third region III of the first substrate 100, and a plurality of bit lines 440 may be spaced apart from each other in the first direction D1. The dummy bit line 445 may be disposed on a portion of the third region III adjacent to the fourth region IV of the first substrate 100.

In example embodiments, each of the bit lines 440 may contact the first extension portions of the channels 125 that are arranged along the third direction D3 and disposed at opposite sides in the second direction D2 of each of the bit lines 440, and the dummy bit line 445 may contact the first extension portions of the channels 125 that are arranged along the third direction D3 and disposed at opposite sides in the second direction D2 of the dummy bit line 445. Each of the bit lines 440 and the dummy bit line 445 may contact sidewalls in the second direction D2 of the first gate insulation pattern 360 and the liner 400 surrounding the first extension portion of each of the channels 125.

In an example embodiment, each of the bit line 440 and the dummy bit line 445 may include, e.g., polysilicon doped with n-type impurities. Alternatively, each of the bit line 440 and the dummy bit line 445 may include, e.g., a metal, a metal nitride, a metal silicide, etc.

In example embodiments, a first width in the first direction D1 of the channel 125 may be greater than a second width in the first direction D1 of the bit line 440.

The capping layer 460 may be disposed on an upper end of the air spacer 415, an upper surface of the liner 400, an upper surface and an upper sidewall of the bit line 440, an upper surface and an upper sidewall of the dummy bit line 445, the upper surface of the second mask 320 and the upper surface of the second insulating interlayer 435 in the first region I of the first substrate 100, and may cover a sidewall of an upper portion of the capacitor structure. The capping layer 460 may include materials having low gap-fill characteristics, e.g., silicon carbonitride (SiCN), silicon boronitride (SiBN), silicon oxycarbide (SiOC), silicon oxycarbonitride (SiOCN), silicon nitride (SiN), silicon oxide (SiO₂), etc.

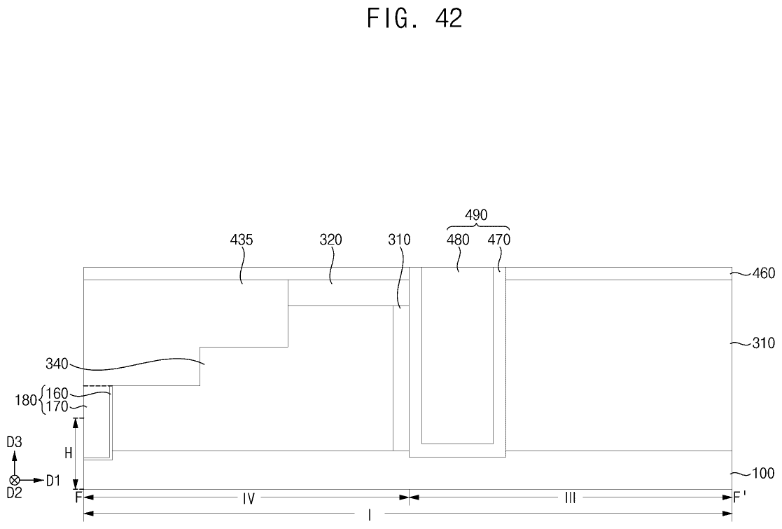

Referring to FIG. 42 together with FIGS. 1 to 6, the blocking structure 490 may extend through the capping layer 460 and the third division structure between neighboring ones of the channels 125 in the second direction D2 on a portion of the third region III adjacent to the fourth region IV of the first substrate 100 and may contact the upper surface of the first substrate 100. The blocking structure 490 may be disposed at an opposite side of the bit line 440 with respect to the channel 125. In an example embodiment, the blocking structure 490 may have a shape of, e.g., polygon such as a rectangle in a plan view, however, the inventive concept is not limited thereto.

In example embodiments, the blocking structure 490 may include a second blocking pattern 480 extending in the third direction D3 and a first blocking pattern 470 covering a sidewall and a lower surface of the second blocking pattern 480. The first blocking pattern 470 may include an insulating nitride, e.g., silicon nitride, and the second blocking pattern 480 may include an oxide, e.g., silicon oxide.

The capacitor structure may include a capacitor 550 and a plate electrode 560, and the capacitor 550 may include first and second capacitor electrodes 520 and 540 and a dielectric pattern 530.

In example embodiments, the first capacitor electrode 520, the dielectric pattern 530 and the second capacitor electrode 540 may be sequentially stacked in a space between the second extension portions of the channels 125 stacked in the third direction D3, between the second extension portions of the channels 125 disposed at the lowermost layer and the upper surface of the first substrate 100, and between the second extension portions of the channels 125 disposed at the uppermost layer and the second mask 320 on the third region III of the first substrate 100, and the plate electrode 560 may fill a remaining portion of the space and a space between the second extension portions of neighboring ones of the channels 125 in the second direction D2.

Thus, the plate electrode 560 may include a vertical extension portion extending in the third direction D3 and a horizontal extension portion extending from each of opposite sidewalls in the second direction D2 of the horizontal extension portion. Each of the capacitor 550 and the plate electrode 560 may extend in the first direction D1 on the third region III of the first substrate 100.

In example embodiments, the capacitor structure may extend through the capping layer 460 and the third division structure and may contact a sidewall in the first direction D1 of the blocking structure 490. Thus, the capacitor structure may be disposed at an opposite side of the bit line 440 in the second direction D2 with respect to the channel 125.

A metal silicide pattern 580 may be disposed at a portion of each of the channels 125 contacting the first capacitor electrode 520.

Each of the first and second capacitor electrodes 520 and 540 may include a metal, e.g., titanium, tantalum, etc., or a metal nitride, e.g., titanium nitride, tantalum nitride, etc., the dielectric pattern 530 may include a metal oxide having a high dielectric constant, e.g., hafnium oxide, zirconium oxide, etc., the plate electrode 560 may include, e.g., doped or undoped silicon-germanium, and the metal silicide pattern 580 may include, e.g., titanium silicide, tantalum silicide, etc.

The word line and the bit line 440 extending in the first and second directions D1 and D2, respectively, the channel 125 surrounded by the word line and contacting the bit line 440, and the capacitor 550 electrically connected to the channel 125 on the third region III of the first substrate 100 may collectively form the memory cell, and a plurality of memory cells may be disposed in each of the first to third directions D1, D2 and D3 on the third region III of the first substrate 100.

The third and fourth insulating interlayers 600 and 630, the first and second bonding layers 640 and 830, the sixth and fifth insulating interlayers 820 and 740 and the second substrate 700 may be sequentially stacked on the capping layer 460 in the third direction D3.

The first contact plug 612 may extend through the third insulating interlayer 600 and the capping layer 460 to contact an upper surface of the bit line 440, the second contact plug 614 may extend through the third insulating interlayer 600 to contact an upper surface of the plate electrode 560 of the capacitor structure, and the third contact plug 616 may extend through the third insulating interlayer 600, the capping layer 460, the second mask 320 and the eighth division pattern 340 or extend through the third insulating interlayer 600, the capping layer 460 and the second insulating interlayer 435 to contact an upper surface of the conductive pad 430.

The first to third wiring structures 622, 624 and 626 may be disposed in the fourth insulating interlayer 630 to contact upper surfaces of the first to third contact plugs 612, 614 and 616, respectively. The first and second bonding layers 640 and 830 may include first and second bonding patterns 645 and 835, respectively. The first and second bonding patterns 645 and 835 may contact each other, and each of the first bonding patterns 645 may contact a corresponding one of the first to third wiring structures 622, 624 and 626 to be electrically connected thereto.

The fourth wiring structure 800 may be disposed in the sixth insulating interlayer 820 and may contact corresponding one of the second bonding patterns 835 to be electrically connected thereto. The fourth contact plug 750 may be disposed in the fifth insulating interlayer 740 and may contact the fourth wiring structure 800.

The first to third contact plugs 612, 614 and 616, the first to third wiring structures 622, 624 and 626, the fourth contact plug 750, and the fourth wiring structure 800 may be disposed on the first region I of the first substrate 100, that is, under the first region I of the second substrate 700.

A second gate structure 730 including a second gate insulation pattern 710 and a second gate electrode 720 may be disposed under the first region I of the second substrate 700, and first impurity regions 705 may be disposed at lower portions, respectively, of the second substrate 700 adjacent to the second gate structure 730. The second gate structure 730 and the first impurity regions 705 may collectively form a transistor.

As the degree of integration of the semiconductor device increases, parasitic coupling capacitance between the first gate structure and the contact portion of the channel 125 may increase, which may degrade the reliability of the semiconductor device.

However, in the semiconductor device, the air spacer 415 including air having a low dielectric constant may be interposed between the first gate structure and the contact portion of the channel 125. Accordingly, compared to when an insulation pattern including an insulating material having a higher dielectric constant than air (e.g., silicon oxide) is interposed between the first gate structure and the contact portion of the channel 125, the parasitic coupling capacitance may be reduced, thereby improving the reliability of the semiconductor device.

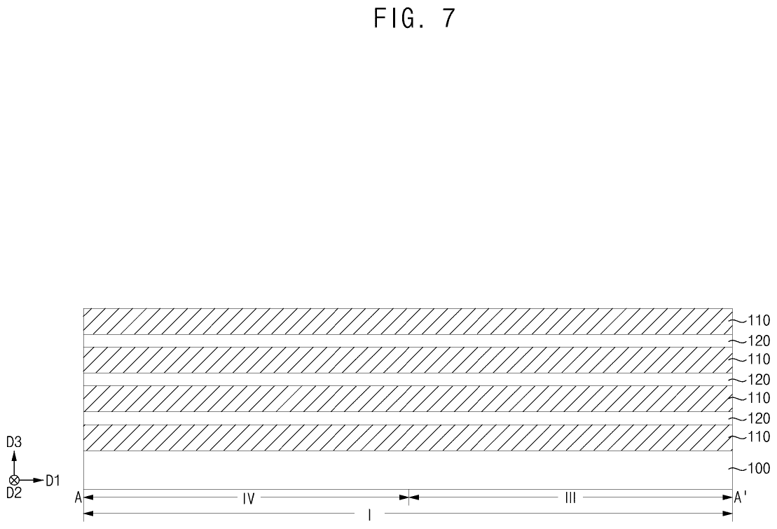

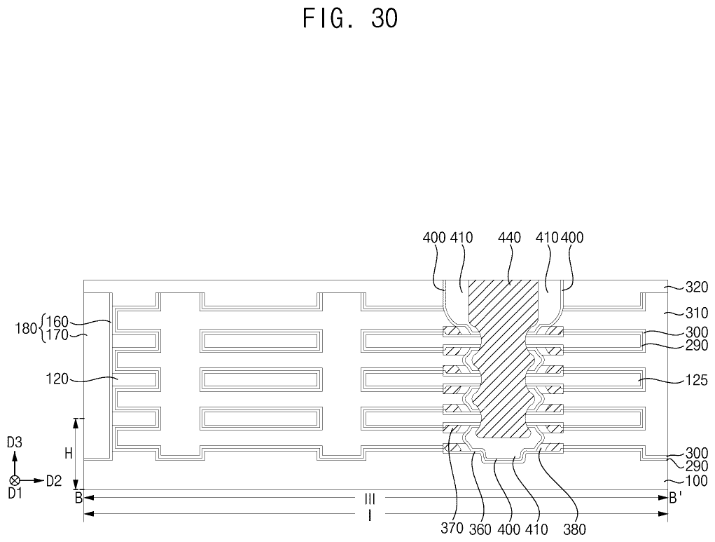

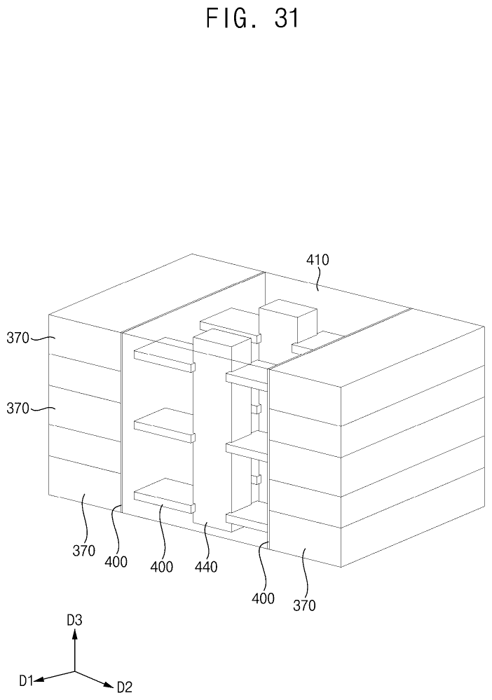

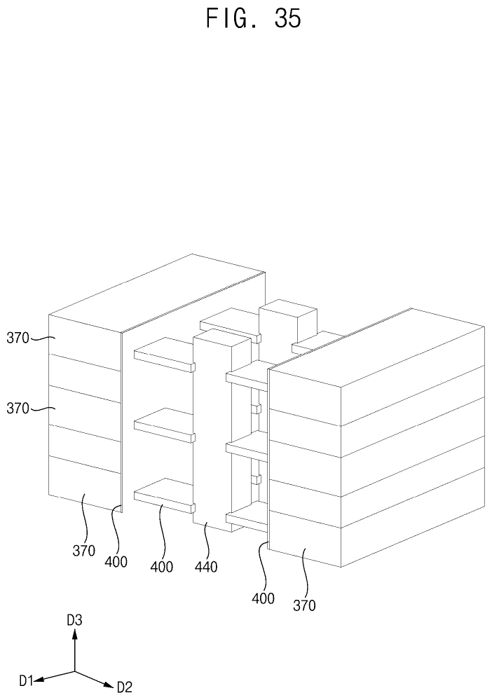

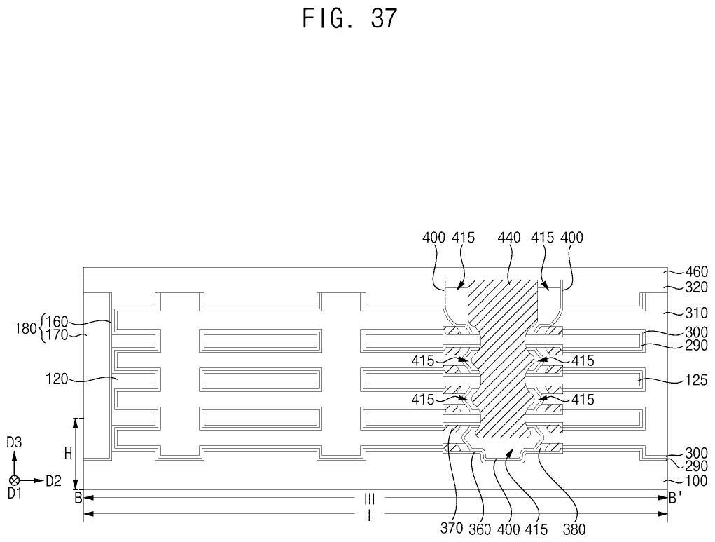

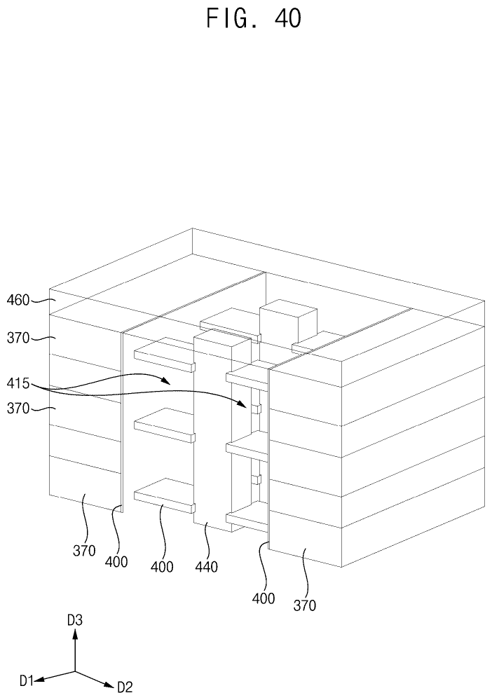

FIGS. 7 to 46 are horizontal cross-sectional views, vertical cross-sectional views and perspective views illustrating a method of manufacturing a semiconductor device in accordance with example embodiments.

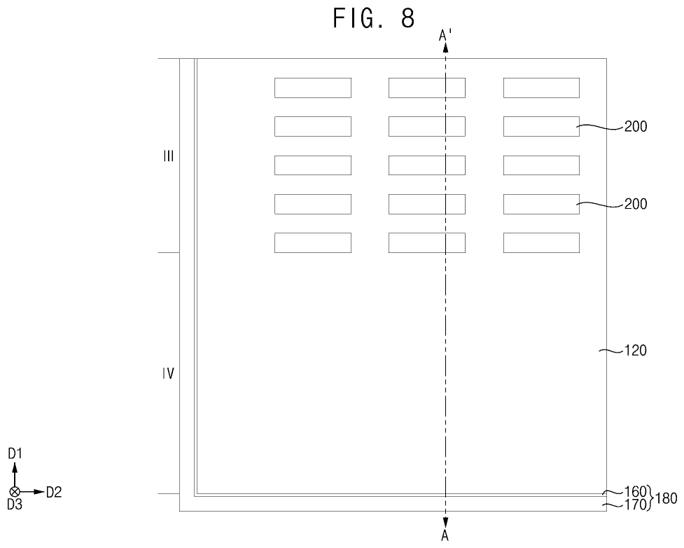

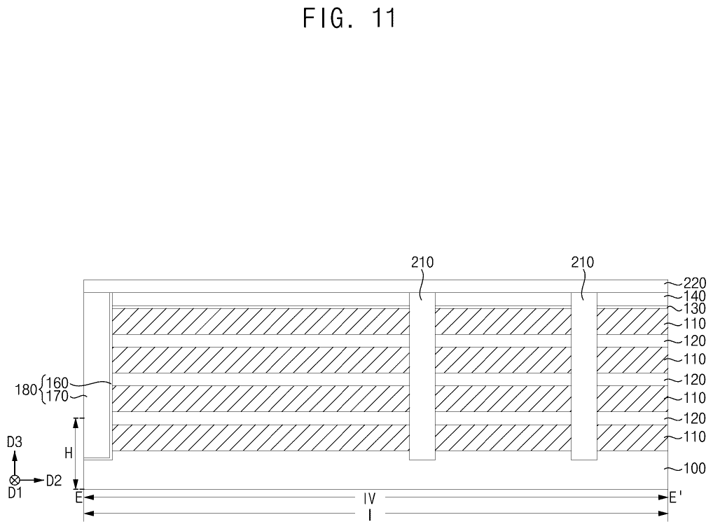

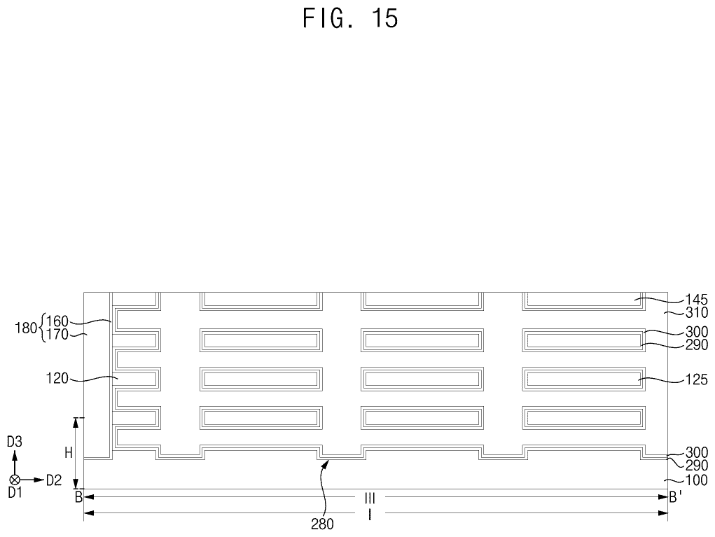

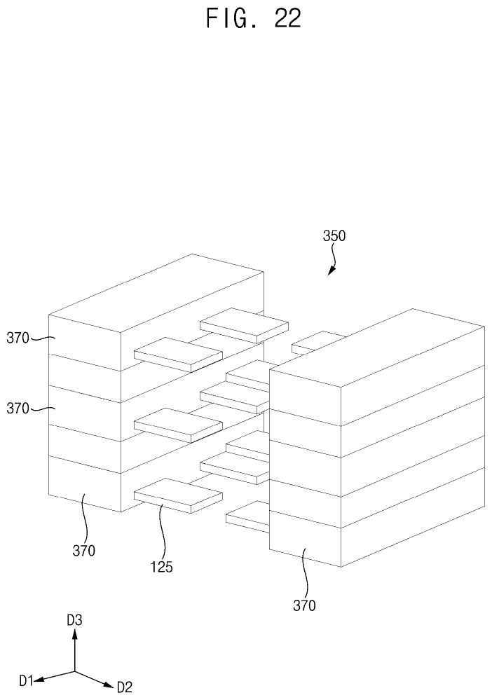

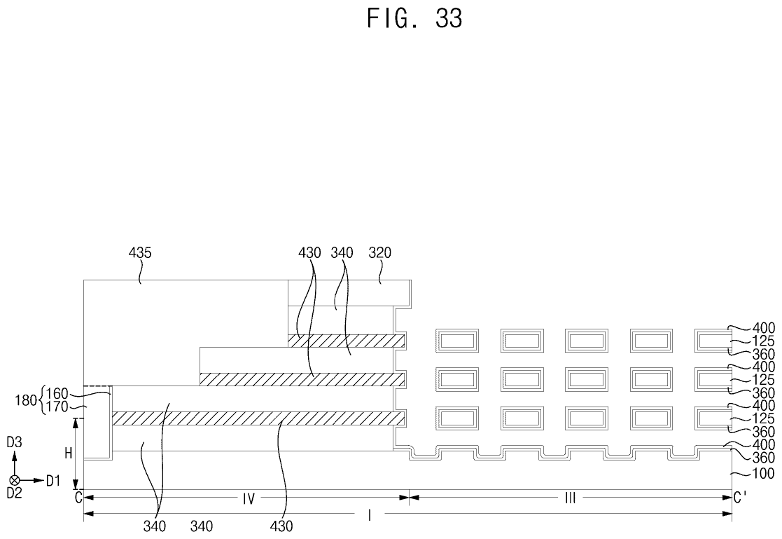

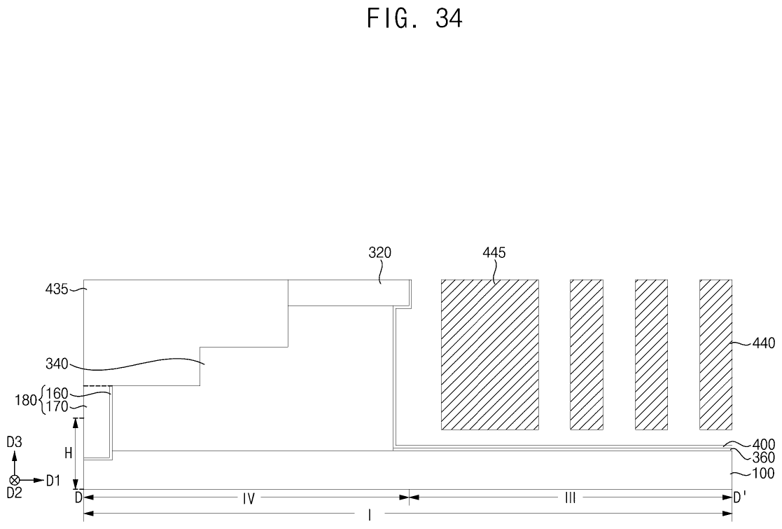

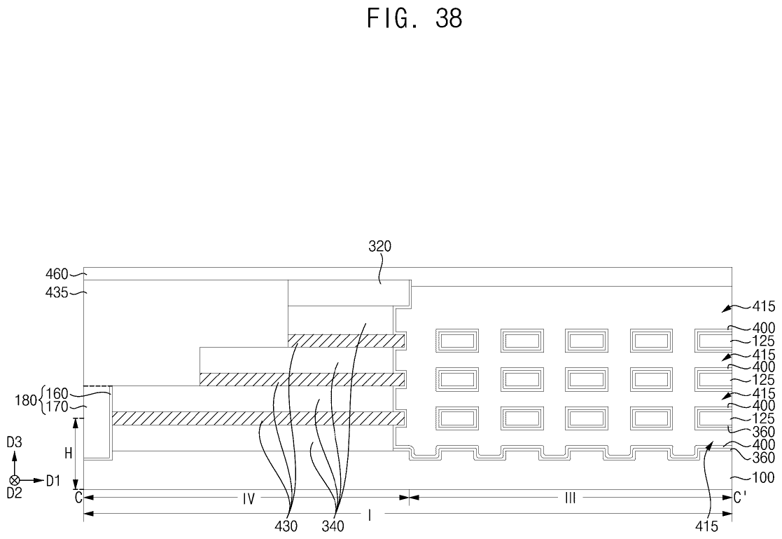

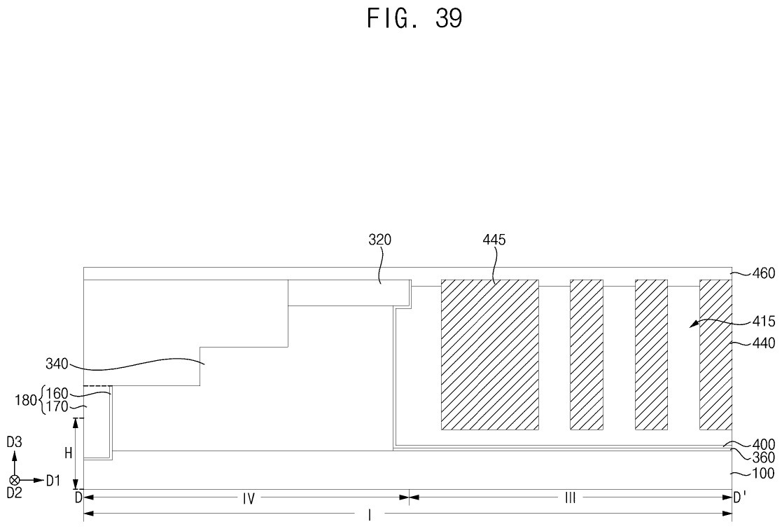

Particularly, FIGS. 8, 10, 12, 14, 16, 18, 20, 23, 26, 29, 36, 41 and 43 are horizontal cross-sectional views at heights H of corresponding vertical cross-sectional views, respectively. FIGS. 7, 9, 28 and 45 are vertical cross-sectional views taken along lines A-A′ of corresponding horizontal cross-sectional views, respectively. FIGS. 15, 19, 21, 24, 30, 32, 37, 44 and 46 are vertical cross-sectional views taken along lines B-B′ of corresponding horizontal cross-sectional views, respectively. FIGS. 33 and 38 are vertical cross-sectional views taken along lines C-C′ of corresponding horizontal cross-sectional views, respectively. FIGS. 34 and 39 are vertical cross-sectional views taken along lines D-D′ of corresponding horizontal cross-sectional views, respectively. FIGS. 11, 13, 17 and 27 are vertical cross-sectional views taken along lines E-E′ of corresponding horizontal cross-sectional views, respectively. FIG. 42 is a vertical cross-sectional view taken along lines F-F′ of a corresponding horizontal cross-sectional view. FIGS. 22, 25, 31, 35 and 40 are perspective views illustrating key portions of a semiconductor device in accordance with example embodiments.

Meanwhile, in each perspective view, the sacrificial mold 410 and the capping layer 460 are illustrated as being transparent.

Referring to FIG. 7, a sacrificial layer 110 and a semiconductor layer 120 may be alternately and repeatedly stacked on a first substrate 100 including first and second regions I and II (refer to FIGS. 1 and 2) to form a mold layer.

FIG. 7 shows that the sacrificial layer 110 and the semiconductor layer 120 are stacked at four levels and three levels, respectively, on the first substrate 100, and the sacrificial layer 110 and the semiconductor layer 120 may be stacked at more or less than four levels and three levels, respectively.

In example embodiments, the mold layer may be formed by an epitaxial growth process using an upper surface of the first substrate 100 as a seed.

In an example embodiment, the semiconductor layer 120 may include, e.g., silicon, and the sacrificial layer 110 may include a material having a selectivity with respect to the semiconductor layer 120, e.g., silicon-germanium.

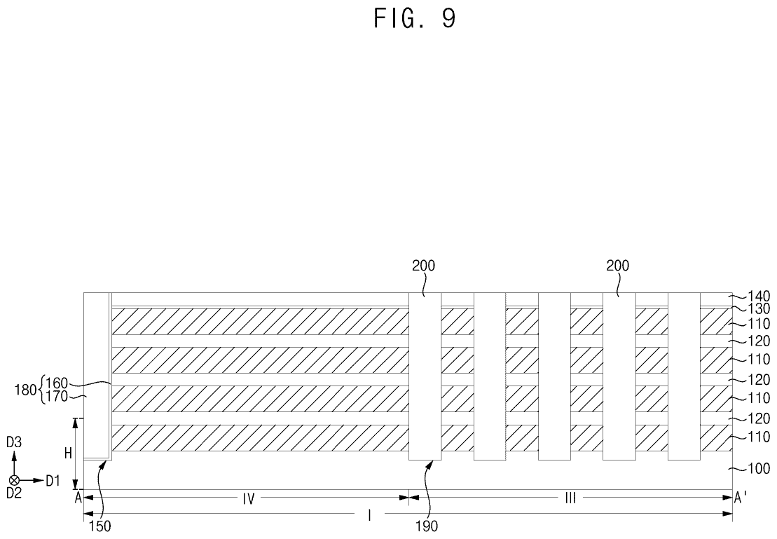

Referring to FIGS. 8 and 9, an insulation pad layer 130 and a first mask layer 140 may be sequentially stacked in the third direction D3 on the mold layer, a dry etching process may be performed on the first mask layer 140, the insulation pad layer 130 and the mold layer to form a first opening 150 exposing the upper surface of the first substrate 100, and a first division structure 180 may be formed in the first opening 150.

The insulation pad layer 130 may include an oxide, e.g., silicon oxide, and the first mask layer 140 may include an insulating nitride, e.g., silicon nitride.

In example embodiments, the first division structure 180 may have a lattice shape in a plan view, and thus a plurality of memory block regions each of which may have, e.g., a rectangular shape may be defined in each of the first and second directions D1 and D2 on the first region I of the first substrate 100. However, the inventive concept is not limited thereto, and each of the memory block regions may have other shapes in a plan view. FIGS. 8 and 9 shows a portion of the first division structure 180.

In example embodiments, each of the memory block regions may include third and fourth regions III and IV arranged in the first direction D1.

In an example embodiment, the first division structure 180 may include a first division pattern 160 on a sidewall and a bottom of the first opening 150 and a second division pattern 170 fill a remaining portion of the first opening 150. A sidewall and a lower surface of the second division pattern 170 may be covered by the first division pattern 160. The first division pattern 160 may include an insulating nitride, e.g., silicon nitride, and the second division pattern 170 may include an oxide, e.g., silicon oxide.

For example, a dry etching process may be performed on the first mask layer 140, the insulation pad layer 130 and the mold layer to form a second opening 190 exposing the upper surface of the first substrate 100, and a third division pattern 200 may be formed in the second opening 190.

In example embodiments, the third division pattern 200 may have a bar shape extending in the second direction D2 in a plan view, and a plurality of third division patterns 200 may be spaced apart from each other in each of the first and second directions D1 and D2. The third division pattern 200 may include an oxide, e.g., silicon oxide.

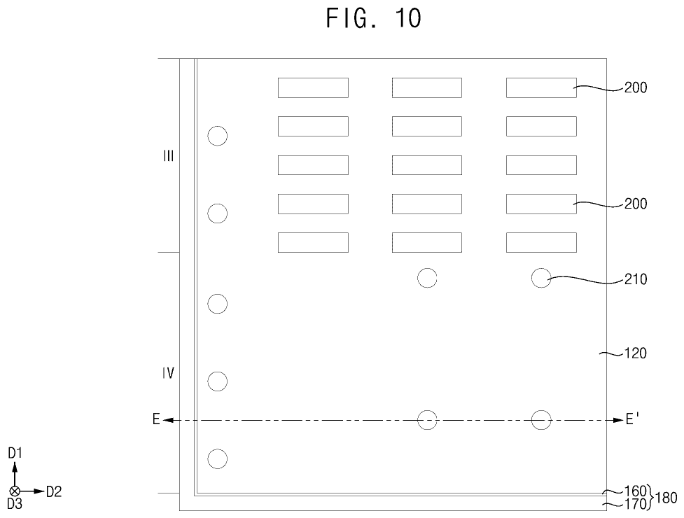

Referring to FIGS. 10 and 11, a dry etching process may be performed on the first mask layer 140, the insulation pad layer 130 and the mold layer to form a third opening exposing the upper surface of the first substrate 100, and a support pattern 210 may be formed in the third opening.

In example embodiments, the support pattern 210 may have a shape of, e.g., a circle, an ellipse, a polygon, a polygon with rounded corners, etc., in a plan view, and a plurality of support patterns 210 may be spaced apart from each other in each of the first and second directions D1 and D2. The support pattern 210 may include an insulating nitride, e.g., silicon nitride.

A first insulating interlayer 220 may be formed on the first mask layer 140, the first division structure 180, the third division pattern 200 and the support pattern 210. The first insulating interlayer 220 may include an oxide, e.g., silicon oxide.

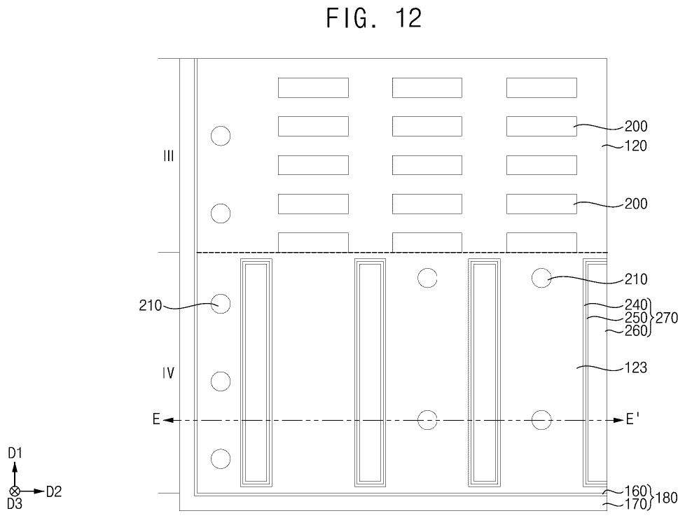

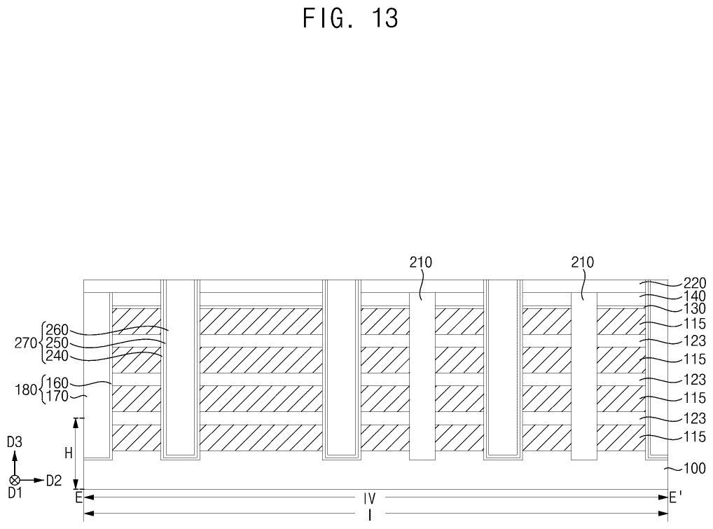

Referring to FIGS. 12 and 13, a dry etching process may be performed on the first insulating interlayer 220, the first mask layer 140, the insulation pad layer 130 and the mold layer to form a fourth opening 230 exposing the upper surface of the first substrate 100, and a second division structure 270 may be formed in the fourth opening 230.

In example embodiments, the second division structure 270 may have a bar shape extending in the first direction D1 in a plan view, and a plurality of second division structures 270 may be spaced apart from each other in the second direction D2. In example embodiments, each of the second division structures 270 may overlap in the first direction D1 a portion of the mold layer between neighboring ones of the third division patterns 200 in the second direction D2.

In an example embodiment, the second division structure 270 may include fourth to sixth division patterns 240, 250 and 260 sequentially stacked from a sidewall and a bottom of the fourth opening 230. Each of the fourth and sixth division patterns 240 and 260 may include an oxide, e.g., silicon oxide, and the fifth division pattern 250 may include an insulating nitride, e.g., silicon nitride.

As the second division structure 270 is formed, portions of the sacrificial layer 110 and the semiconductor layer 120 included in a portion of the mold layer in the fourth region IV may be transformed into a first sacrificial pattern 115 and a semiconductor pattern 123, respectively.

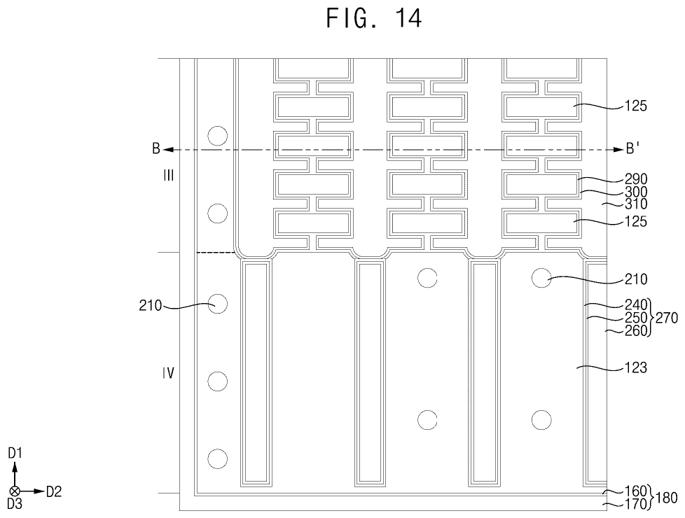

Referring to FIGS. 14 and 15, a dry etching process may be performed on the first insulating interlayer 220, the first mask layer 140, the insulation pad layer 130 and the mold layer to form a fifth opening 280 exposing the upper surface of the first substrate 100.

In example embodiments, the fifth opening 280 may extend in the first direction D1 between neighboring ones of the third division patterns 200 in the second direction D2, and a plurality of fifth openings 280 may be spaced apart from each other in the second direction D2 in the third region III. Each of the fifth openings 280 may be aligned with a corresponding one of the second division structure 270 in the first direction D1 and may extend through a portion of the fourth division pattern 240 at an end portion in the first direction D1 of the second division structure 270 to expose a sidewall of the fifth division pattern 250.

As the fifth openings 280 are formed, portions of the sacrificial layer 110 and the semiconductor layer 120 between neighboring ones of the third division patterns 200 in the first direction D1 and between the fifth openings 280 on the first region I of the first substrate 100 may be transformed into a second sacrificial pattern and a channel 125, respectively, and portions of the insulation pad layer 130 and the first mask layer 140 on the second sacrificial pattern may remain as an insulation pad and a first mask 145.

A wet etching process may be performed through the fifth opening 280 to remove a portion of the second sacrificial pattern in the third region III, and most portion of the third division pattern 200 adjacent to the fifth opening 280 in the third region III and the insulation pad may also be removed.

Thus, a first gap may be formed between neighboring ones of the channels 125 in the third direction D3, between an uppermost one of the channels 125 and the first mask 145, and between a lowermost one of the channels 125 and the upper surface of the first substrate 100. Additionally, the first gap may be enlarged in the first direction D1, so that a portion of the third division pattern 200 at the same level as each of the channels 125 may remain, and other portions of the third division pattern 200 may be removed.

First and second insulation layers may be sequentially stacked on an inner wall of the first gap, a sidewall and a bottom of the fifth opening 280 and the first insulating interlayer 220, a seventh division layer may be formed on the second insulation layer to fill the first gap and the fifth opening 280, and a planarization process may be performed on the seventh division layer, the first and second insulation layers, the first insulating interlayer 220 and the second division structure 270 until an upper surface of the first mask 145 is exposed. Thus, a third division structure including first and second insulation patterns 290 and 300 and a seventh division pattern 310 may be formed in the first gap and the fifth opening 280, and the first insulating interlayer 220 may be removed.

The first insulation pattern 290 and the seventh division pattern 310 may include an oxide, e.g., silicon oxide, and the second insulation pattern 300 may include an insulating nitride, e.g., silicon nitride. The third division pattern 200 remaining between the channels 125 may be merged with the first insulation pattern 290, and hereinafter, the merged structure may be referred to as a first insulation pattern 290. In some embodiments, the first insulation pattern 290 and a portion of the fourth division pattern 240 exposed by the fifth opening 280 may contact each other to be merged with each other.

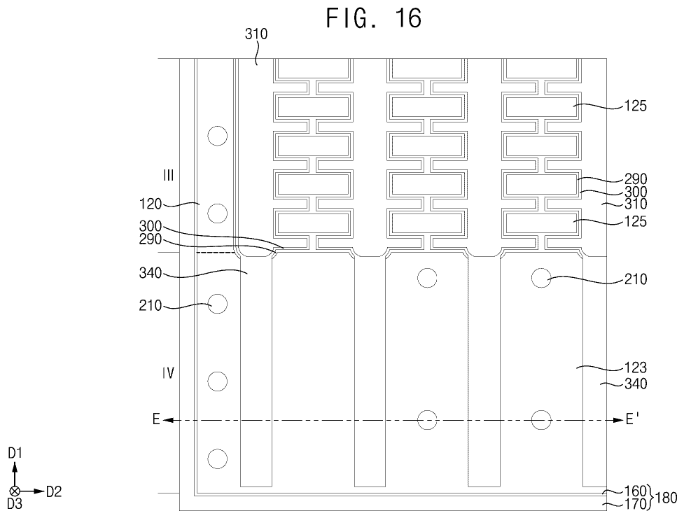

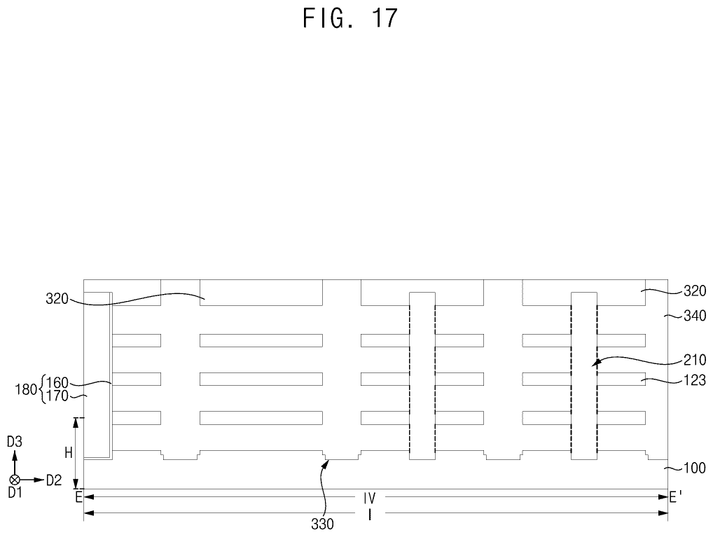

Referring to FIGS. 16 and 17, a second mask 320 may be formed on the first mask layer 140, the first mask 145, the second division structure 270 and the third division structure, a dry etching process may be performed using the second mask 320 as an etching mask to remove the second division structure 270 so that a sixth opening 330 exposing the upper surface of the first substrate 100 may be formed. A portion of the first sacrificial pattern 115 adjacent to the sixth opening 330 may be removed through the sixth opening 330, and the insulation pad layer 130 may also be removed.

Thus, a second gap may be formed between ones of the semiconductor patterns 123 neighboring in the third direction D3, between an uppermost one of the semiconductor patterns 123 and the first mask layer, and between a lowermost one of the semiconductor patterns 123 and the first substrate 100.

The second mask 320 may include an insulating nitride, e.g., silicon nitride, and the first mask layer 140 and the first mask 145 may be merged to the second mask 320. Hereinafter, the merged structure may be referred to as the second mask 320.

An eighth division layer may be formed on the first substrate 100 and the second mask 320 to fill the second gap and the sixth opening 330, and a planarization process may be performed on the eighth division layer until an upper surface of the second mask 320 is exposed to form an eighth division pattern 340 in the second gap and the sixth opening 330. The eighth division pattern 340 may include an insulating nitride, e.g., silicon nitride, and thus, in some embodiments, the support pattern 210 may be merged to the eighth division pattern 340.

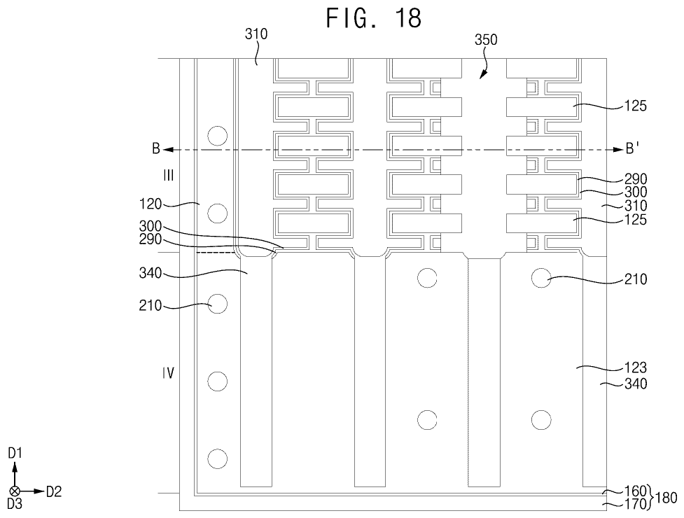

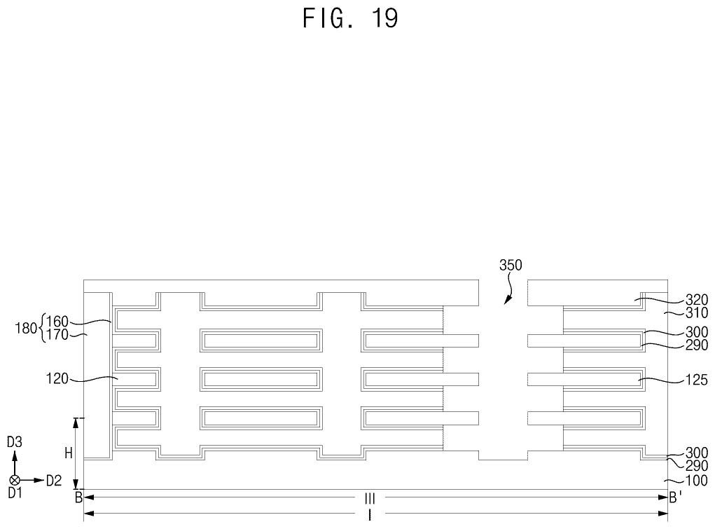

Referring to FIGS. 18 and 19, the second mask 320 and the third division structure may be partially removed by, e.g., a dry etching process to form a seventh opening 350 exposing the upper surface of the first substrate 100.

In example embodiments, a sidewall of an end portion in the second direction D2 of the channel 125 may be exposed by the seventh opening 350.

A portion of the third division structure adjacent to the seventh opening 350 may be removed by, for example, a wet etching process.

Referring to FIGS. 20 to 22, a first gate insulation pattern 360 may be formed to cover the upper surface of the first substrate 100 exposed by the seventh opening 350, and upper and lower surfaces and a sidewall of the end portion of the channel 125.

The first gate insulation pattern 360 may be formed by, for example, a thermal oxidation process.

A first gate electrode layer may be formed on a sidewall and a bottom of the seventh opening 350 and the first gate insulation pattern 360, and a wet etching process or a dry etching process may be performed on the first gate electrode layer to form a first gate electrode 370 surrounding a portion of the first gate insulation pattern 360.

A first gate mask layer may be formed on the sidewall and the bottom of the seventh opening 350, the first gate insulation pattern 360 and the first gate electrode 370, and a wet etching process or a dry etching process may be performed on the first gate mask layer to form a first gate mask 380 surrounding a portion of the first gate insulation pattern 360 and contacting a sidewall in the second direction D2 of the first gate electrode 370.

The first gate electrode 370, the first gate insulation pattern 360 and the first gate mask 380 collectively form a first gate structure on the first region I of the first substrate 100 and may extend in the first direction D1 to surround the end portion in the second direction D2 of each of the channels 125 in the third region III. Thus, a plurality of first gate structures may be spaced apart from each other in the third direction D3 at each of opposite sides in the second direction D2 of the seventh opening 350. Each of the first gate structures may serve as a word line of the semiconductor device.

Hereinafter, for convenience of explanation, a portion of the channel 125 surrounded by the first gate electrode 370 included in the first gate structure may be referred to as a central portion, and portions extending along the second direction D2 from opposite sides of the central portion of the channel 125 may be respectively referred to as a first extension portion and a second extension portion.

A filling pattern may be formed to fill spaces between the first gate structures spaced apart from each other in the third direction D3. In example embodiments, the filling pattern may be formed by: forming a filling layer at surfaces of the first gate structures adjacent to the seventh opening 350, sidewalls of the seventh division pattern 310, and portions of the first gate insulation patterns 360 covering surfaces of the first extension portions of the channels 125 and the upper surface of the first substrate 100; and performing an etching process on the filling layer to remove portions thereof except for a portion of the filling layer formed between neighboring ones of the first gate structures in the third direction D3. During the etching process, a portion of the first gate insulation pattern 360 covering sidewalls in the second direction D2 of the channels 125 may be removed. Accordingly, the sidewalls in the second direction D2 of the first extension portions of the channels 125 may be exposed.

The filling pattern may include an oxide, for example, silicon oxide. The filling pattern may be merged with the seventh division pattern 310, and hereinafter, the merged structure may be referred to as the seventh division pattern 310.

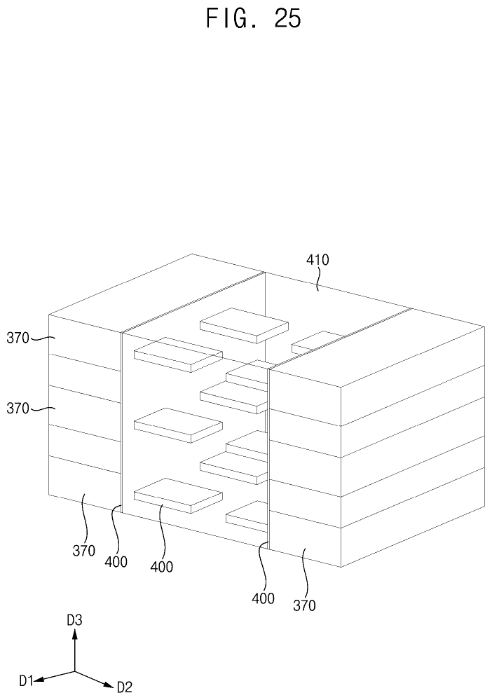

Referring to FIGS. 23 and 25, a liner layer may be formed to cover sidewalls in the second direction D2 of the first gate structures adjacent to the seventh opening 350, surfaces of the portions of the first gate insulation patterns 360 covering the surfaces of the first extension portions of the channels 125 and the upper surface of the first substrate 100, the sidewalls in the second direction D2 of the first extension portions of the channels 125, and sidewalls of the seventh division pattern 310, and a sacrificial mold layer may be formed to fill remaining portions of the seventh opening 350.

The liner layer may be formed by, for example, an atomic layer deposition (ALD) process. A liner 400 and a sacrificial mold 410 may be respectively formed by performing a planarization process on the liner layer and the sacrificial mold layer until the upper surface of the second mask 320 is exposed.

The liner 400 may include an insulating nitride, e.g., silicon nitride, an oxide, e.g, silicon oxide, silicon carbonitride, etc., and the sacrificial mold 410 may include a material having a high etch selectivity with respect to the liner 400 such as an oxide, e.g., silicon oxide, an insulating nitride, e.g., silicon nitride, etc.

Referring to FIGS. 26 and 27, the eighth division pattern 340 may be removed by, e.g., a dry etching process to form an eighth opening 420 exposing the upper surface of the first substrate 100, and e.g., a wet etching process may be performed through the eighth opening 420 to remove the semiconductor pattern 123 to form a third gap, a conductive pad layer may be formed to fill the third gap, and e.g., a wet etching process may be performed on the conductive pad layer to form a conductive pad 430 in the third gap.

In example embodiments, the conductive pad 430 may extend in the first direction D1 in the fourth region IV, and a plurality of conductive pads 430 may be spaced apart from each other in the second direction D2. Additionally, a plurality of conductive pads 430 may be spaced apart from each other in the third direction D3.

A ninth division layer may be formed to fill the eighth opening 420, and a planarization process may be performed on the ninth division layer until the upper surface of the second mask 320 is exposed to form a ninth division pattern in the eighth opening 420. The ninth division pattern may include an insulating nitride, e.g., silicon nitride, and may contact the eighth division pattern 340 between the conductive pads 430 spaced apart from each other in the third direction D3 to be merged thereto. Hereinafter, the eighth division pattern 340 together with the ninth division pattern merged thereto may be referred to as the eighth division pattern 340.

Referring to FIG. 28, the second mask 320, the eighth division pattern 340 and the conductive pad 430 in the fourth region IV may be partially removed by, e.g., a dry etching process to form a ninth opening exposing an upper surface of the eighth division pattern 340.

In example embodiments, after the dry etching process, each of the conductive pads 430 and a portion of the eighth division pattern 340 thereon may collectively form a step layer extending in the first direction D1, and a stack structure including the conductive pads 430 and the eighth division patterns 340 may have a staircase structure having a length decreasing from a bottom toward a top thereof in a stepwise manner. During the dry etching process, upper portions of the first and second division patterns 160 and 170 contacting an end portion in the first direction D1 of the conductive pad 430 may also be removed.

A second insulating interlayer 435 may be formed to fill the ninth opening. The second insulating interlayer 435 may include an oxide, e.g., silicon oxide, and in some embodiments, may be merged to the second division pattern 170.

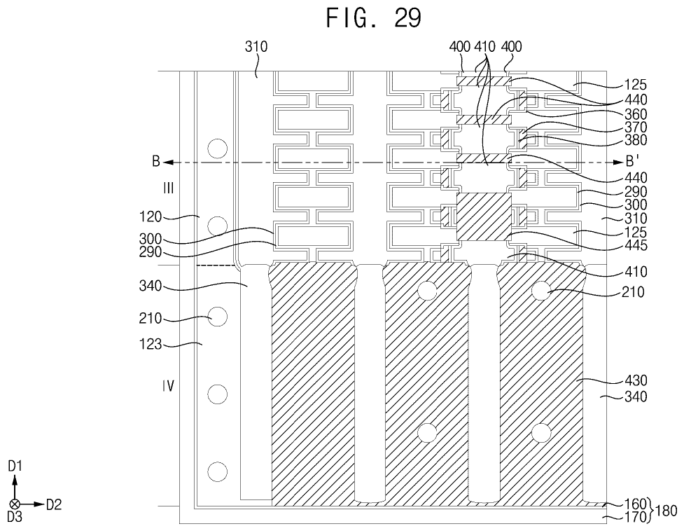

Referring to FIGS. 29 to 31, the sacrificial mold 410 may be partially etched by, e.g., a dry etching process on the first region I of the first substrate 100 to form a first trench.

Portions of the liner 400 and the first gate insulation patterns 360 formed at end portions in the second direction D2 of the first extension portions of the channels 125 that are arranged in the third direction D3 and disposed at opposite sides of the sacrificial mold 410 may be removed together. Accordingly, the end portions in the second direction D2 of the first extension portions of the channels 125 arranged in the third direction D3 may be exposed.

A bit line layer may be formed in the first trench, and an upper portion of the bit line layer may be planarized to form a bit line 440. Accordingly, the bit line 440 formed in the first trench and extending in the third direction D3 may be electrically connected to the channels 125 disposed in the third direction D3 by contacting the end portions in the second direction D2 of the first extension portions of the channels 125 disposed in the third direction D3.

In example embodiments, a plurality of bit lines 440 may be formed to be spaced apart from each other in the first direction D1 in the third region III, and the plurality of bit lines 440 may contact and be electrically connected to the channels 125 disposed in the first direction D1 respectively. However, one of the bit lines 440 disposed in the first direction D1 that is adjacent to the fourth region IV may be a dummy bit line 445.

In an example embodiment, the bit line 440 may include polysilicon doped with n-type impurities. Alternatively, the bit line 440 may include, e.g., a metal, a metal nitride, a metal silicide, etc.

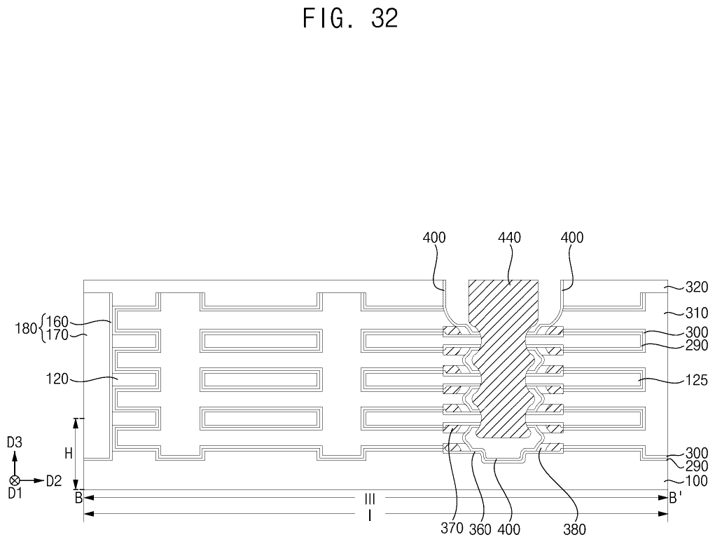

Referring to FIGS. 32 to 35, the sacrificial mold 410 may be selectively removed through, for example, a wet etching process.

In example embodiments, the wet etching process may be performed by a wet etching process using hydrofluoric acid (HF) as an etchant.

By removing the sacrificial mold 410, a surface of the liner 400 and a sidewall and a lower surface of the bit line 440 may be exposed, and a space may be formed between: the first extension portions of the channels 125 spaced apart from each other along the second and third directions D2 and D3, the bit lines 440 spaced apart from each other in the first direction D1, the dummy bit line 445 and the eighth division pattern 340 spaced apart from each other in the first direction D1, the lower surfaces of the bit lines 440 and the upper surface of the first substrate 100, and lower surfaces of the first extension portions of the channels 125 disposed at a lowermost layer and the upper surface of the first substrate 100

An oxide layer may be formed on the exposed sidewall and lower surface of the bit line 440.

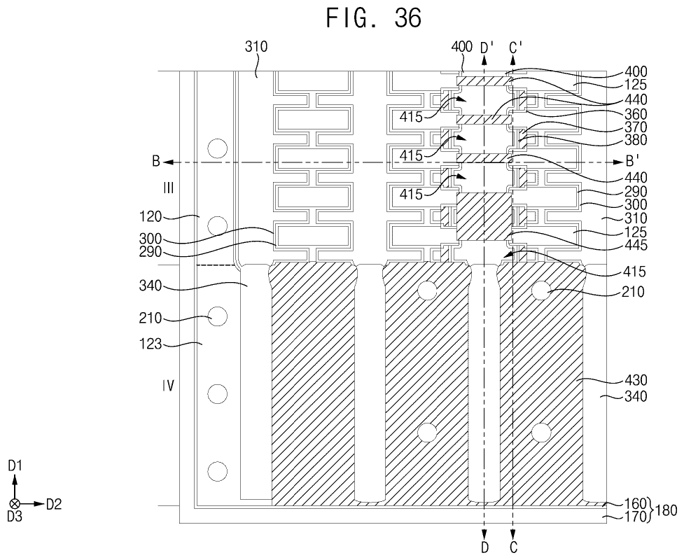

Referring to FIGS. 36 to 40, a capping layer 460 may be formed on an upper end of the space, an upper surface and an upper sidewall of the bit line 440, an uppermost surface of the liner 400, the upper surface of the second mask 320 and an upper surface of the second insulating interlayer 435.

The capping layer 460 may be formed to include an insulating material having low gap-fill characteristics, and accordingly, the space thereunder may remain at least partially unfilled. The space formed by removing the sacrificial mold 410 may be referred to as an air spacer 415. Gap-fill characteristics of the material included in the capping layer 460 may be controlled by adjusting process conditions.

The air spacer 415 may be a spacer including air. The capping layer 460 may include, for example, silicon carbonitride.

In example embodiments, the capping layer 460 may be formed to fill an upper portion of the space. Accordingly, the capping layer 460 may be formed to cover the upper sidewall of the bit line 440.

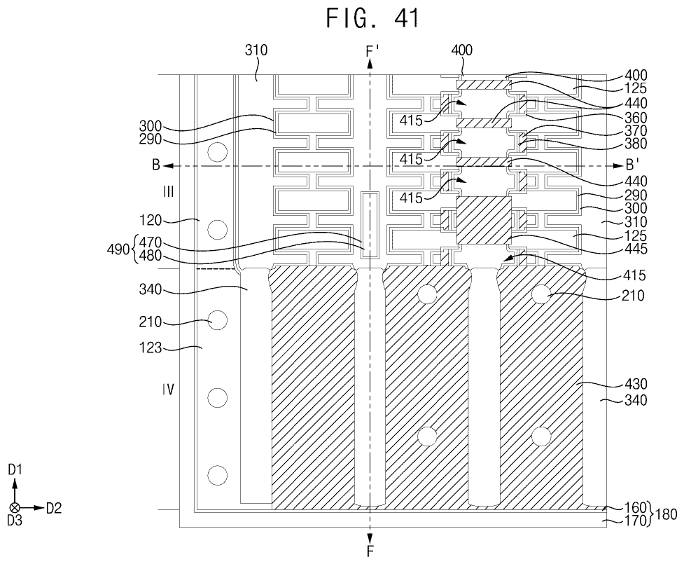

Referring to FIGS. 41 and 42, the seventh division pattern 310 may be partially removed by, e.g., a dry etching process to form a tenth opening exposing the upper surface of the first substrate 100, and a blocking structure 490 may be formed in the tenth opening.

In example embodiments, the blocking structure 490 may be formed in a portion of the third region III adjacent to the fourth region IV and may be disposed between neighboring ones of the channels 125 in the second direction D2 at an opposite side in the second direction D2 of the bit line 440 with respect to the channel 125.

In an example embodiment, the blocking structure 490 may include a first blocking pattern 470 on a sidewall and a bottom of the tenth opening and a second blocking pattern 480 filling a remaining portion of the tenth opening. A sidewall and a lower surface of the second blocking pattern 480 may be covered by the first blocking pattern 470. The first blocking pattern 470 may include an insulating nitride, e.g., silicon nitride, and the second blocking pattern 480 may include an oxide, e.g., silicon oxide.

In an example embodiment, the blocking structure 490 may have a shape of a polygon, e.g., a rectangle in a plan view, however, the inventive concept is not limited thereto.

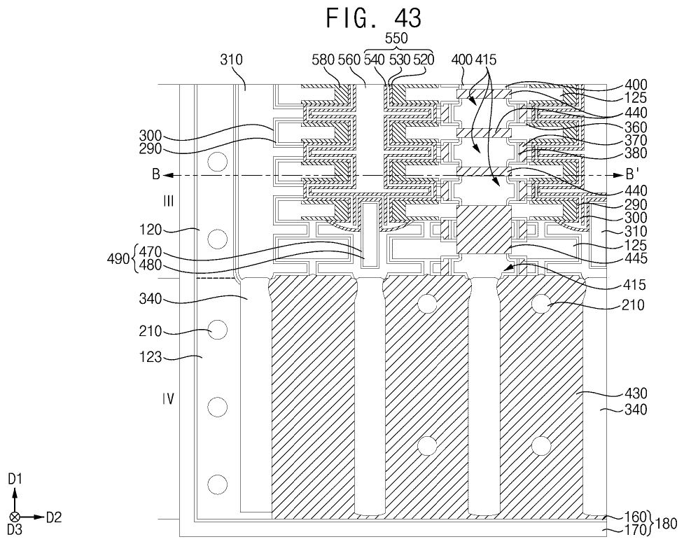

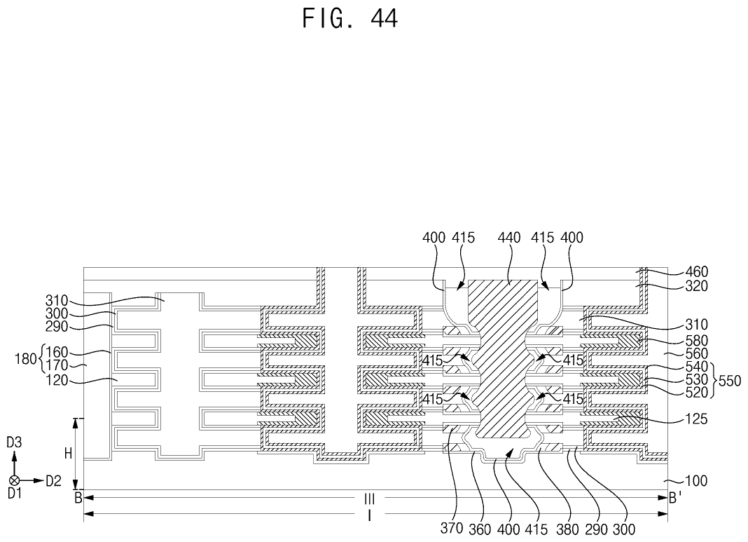

Referring to FIGS. 43 and 44, the capping layer 460, the second mask 320 and the third division structure may be partially removed by, e.g., a dry etching process to form an eleventh opening 510 exposing the upper surface of the first substrate 100.

In example embodiments, the eleventh opening 510 may expose a sidewall in the first direction D1 of the blocking structure 490.

For example, a wet etching process may be performed through the eleventh opening 510 to remove a portion of the seventh division pattern 310 between the channels 125 adjacent to the eleventh opening 510 to form a fourth gap. During the wet etching process, portions of the first and second insulation patterns 290 and 300 on lower and upper surfaces and a sidewall of the second extension portion of the channel 125 may also be removed to expose the second extension portion of the channel 125.

A first capacitor electrode layer, a dielectric layer and a second capacitor electrode layer may be sequentially stacked on an inner wall of the fourth gap, an inner wall of the eleventh opening 510, an upper surface of the capping layer 460 and an upper surface of the blocking structure 490, a plate electrode layer may be formed on the second capacitor electrode layer to fill the fourth gap and the eleventh opening 510, and a planarization process may be performed on the plate electrode layer, the first and second capacitor electrode layers and the dielectric layer until the upper surfaces of the capping layer 460 and the blocking structure 490 are exposed to form a plate electrode 560, first and second capacitor electrodes 520 and 540 and a dielectric pattern 530, respectively, in the fourth gap and the eleventh opening 510.

When the first capacitor electrode layer is formed, a metal silicide pattern 580 may be formed at a portion of the channel 125 contacting the first capacitor electrode layer.

The first and second capacitor electrodes 520 and 540 and the dielectric pattern 530 may collectively form a capacitor 550, and the capacitor 550 and the plate electrode 560 may collectively form a capacitor structure.

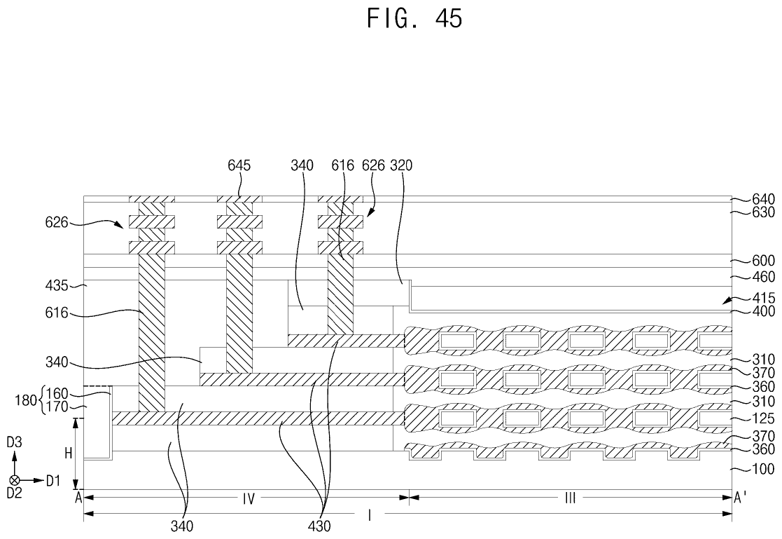

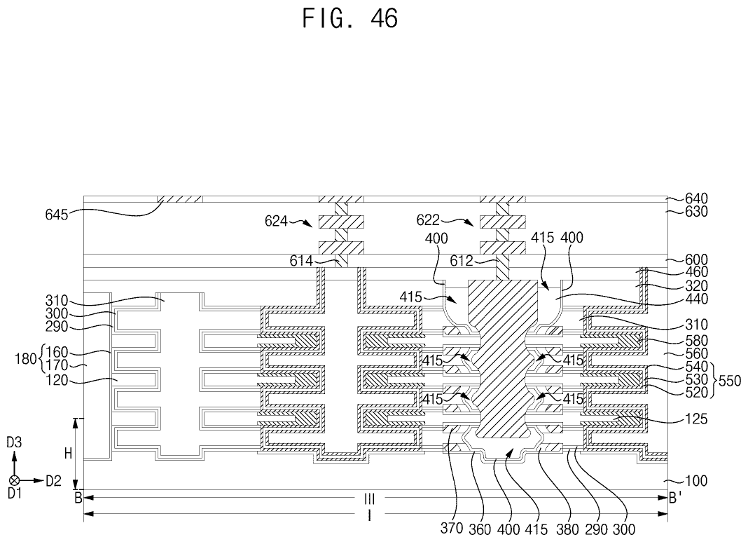

Referring to FIGS. 45 to 46, a third insulating interlayer 600 may be formed on the capacitor structure and the capping layer 460, a first contact plug 612 extending through the third insulating interlayer 600 and the capping layer 460 to contact an upper surface of the bit line 440, a second contact plug 614 extending through the third insulating interlayer 600 to contact an upper surface of the capacitor structure, and a third contact plug 616 extending through the third insulating interlayer 600, the capping layer 460, the second mask 320 and the eighth division pattern 340 or the third insulating interlayer 600, the capping layer 460 and the second insulating interlayer 435 to contact an upper surface of the conductive pad 430 may be formed.

First to third wiring structures 622, 624 and 626 may be formed on the third insulating interlayer 600 and the first to third contact plugs 612, 614 and 616, a fourth insulating interlayer 630 may be formed to cover the first to third wiring structures 622, 624 and 626, and a first bonding layer 640 including a first bonding pattern 645 may be formed on the fourth insulating interlayer 630.

Referring to FIGS. 1 to 6 again, a transistor may be formed on a first region I of a second substrate 700.

The transistor may include a second gate structure 730 having a second gate insulation pattern 710 and a second gate electrode 720, and first impurity regions 705 at a portion of the second substrate 700 adjacent to the second gate structure 730.

A fifth insulating interlayer 740 may be formed to cover the transistor, and a fourth contact plug 750 extending through the fifth insulating interlayer 740 to contact the first impurity region 705 may be formed.

A fourth wiring structure 800 electrically connected to the transistors may be formed on the fifth insulating interlayer 740, a sixth insulating interlayer 820 may be formed on the fifth insulating interlayer 740 to cover the fourth wiring structure 800, and a second bonding layer 830 including a second bonding pattern 835 may be formed on the sixth insulating interlayer 820.

After flipping the second substrate 700, the first and second substrates 100 and 700 may be bonded with each other by contacting the second bonding layer 830 to the first bonding layer 640, and the first and second bonding patterns 645 and 835 may contact each other.

By the above processes, the manufacturing of the semiconductor device may be completed.

As described above, the air spacer 415 may be formed by removing the sacrificial mold 410 to form the space and sealing the upper end of the space using the capping layer 460 including a material having low gap-fill characteristics. Accordingly, parasitic coupling capacitance between the first gate structure and the channel 125 may be reduced by forming the air spacer 415 including air having a low dielectric constant therebetween.

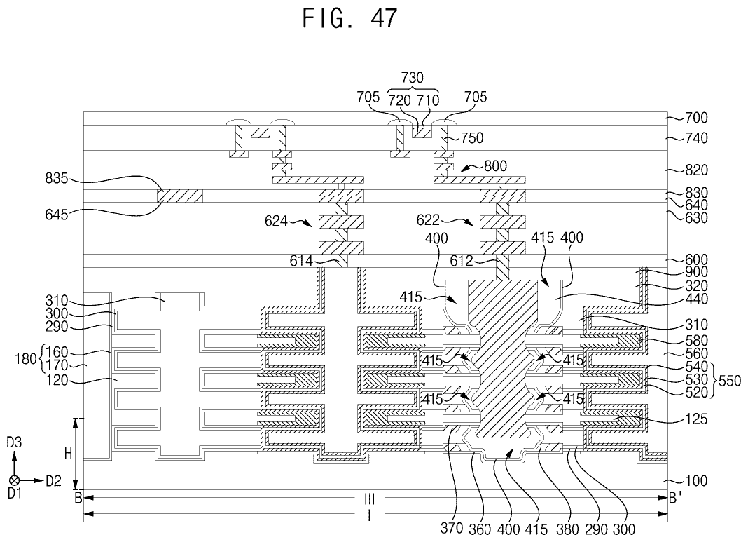

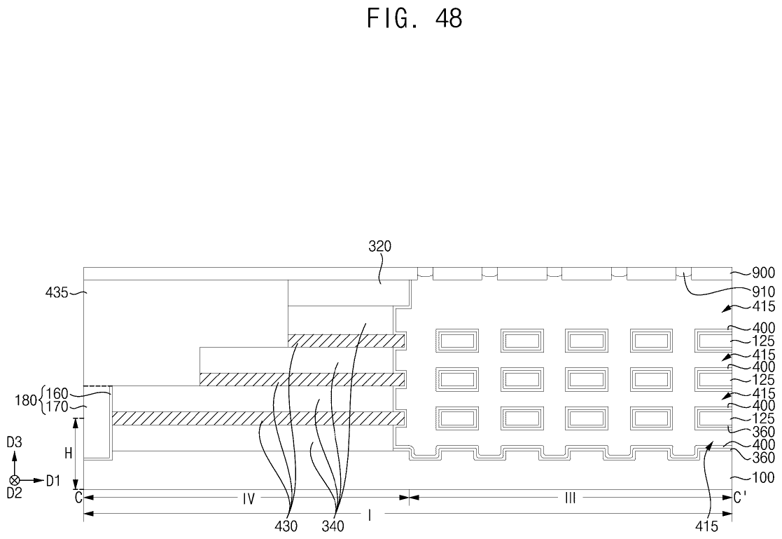

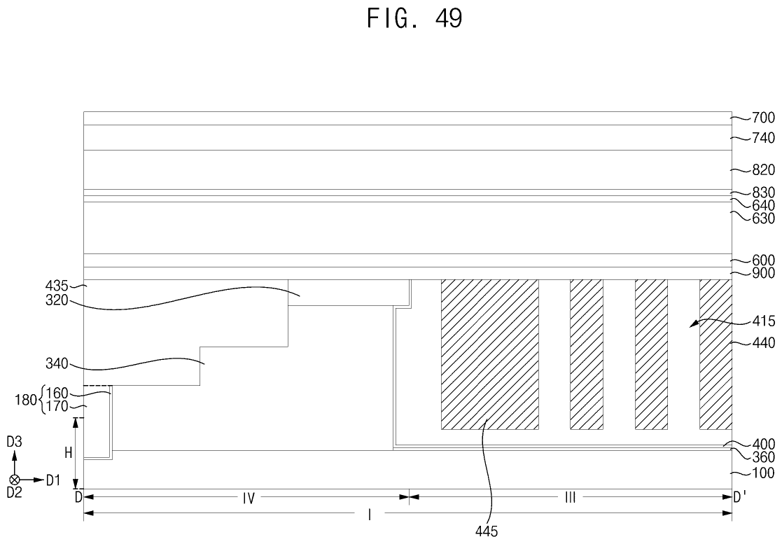

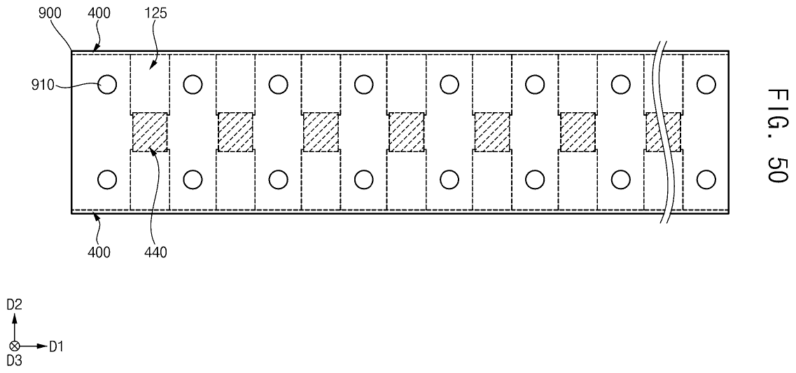

FIGS. 47 to 50 are vertical cross-sectional views and horizontal cross-sectional views illustrating a semiconductor device in accordance with example embodiments. The semiconductor device may be substantially the same as or similar to that of FIGS. 1 to 6, except for further including a seventh insulating interlayer 900 and a capping pattern 910 instead of the capping layer 460. Meanwhile, FIG. 50 is a horizontal cross-sectional view taken through the seventh insulating interlayer 900, illustrating only key portions of the semiconductor device.

Referring to FIGS. 47 to 50, the seventh insulating interlayer 900 may be disposed on the upper end of the air spacer 415, the upper surface of the liner 400, the upper surface of the bit line 440, the upper surface of the dummy bit line 445, the upper surface of the second mask 320 and the upper surface of the second insulating interlayer 435 in the first region I of the first substrate 100, and may cover the sidewall of the upper portion of the capacitor structure. The seventh insulating interlayer 900 may include an insulating nitride, e.g., silicon nitride.

In example embodiments, a lower surface of the seventh insulating interlayer 900 may be disposed at substantially the same height as the upper surface of the second mask 320.

The capping pattern 910 may extend through the seventh insulating interlayer 900 to form the upper end of the air spacer 415. The capping pattern 910 may include, for example, silicon carbonitride.

In example embodiments, the capping pattern 910 may overlap in the third direction D3 portions of the air spacer 415 located between neighboring ones of the channels 125 in the first direction D1.

In example embodiments, a plurality of capping patterns 910 may be spaced apart from each other in the first and second directions D1 and D2. One channel 125 may be disposed between neighboring ones of the capping patterns 910 in the first direction D1, and accordingly, in a plan view, the capping patterns 910 and the channels 125 may be arranged alternately and repeatedly along the first direction D1.

In example embodiments, a lower surface of the capping pattern 910 may be disposed higher than the lower surface of the seventh insulating interlayer 900.

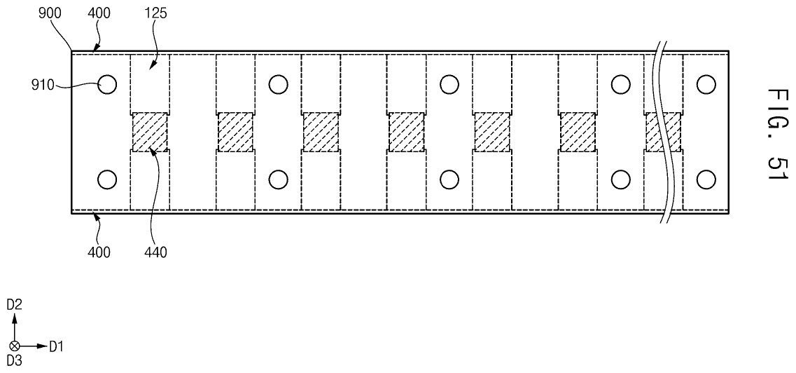

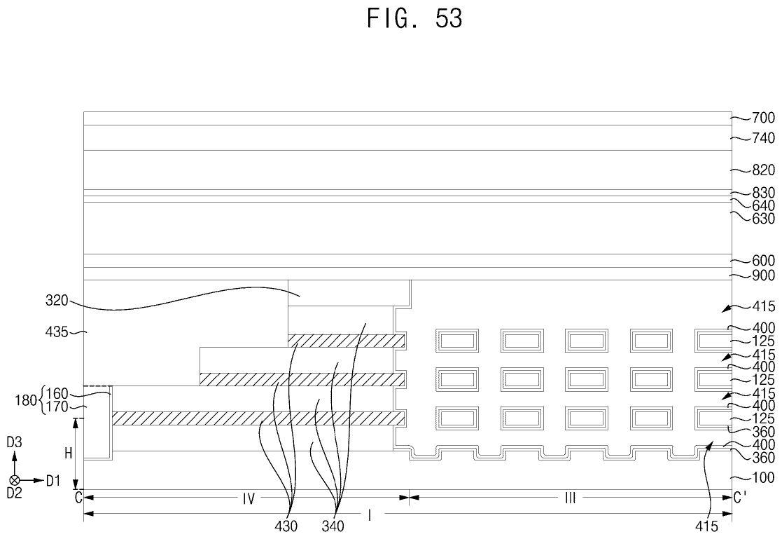

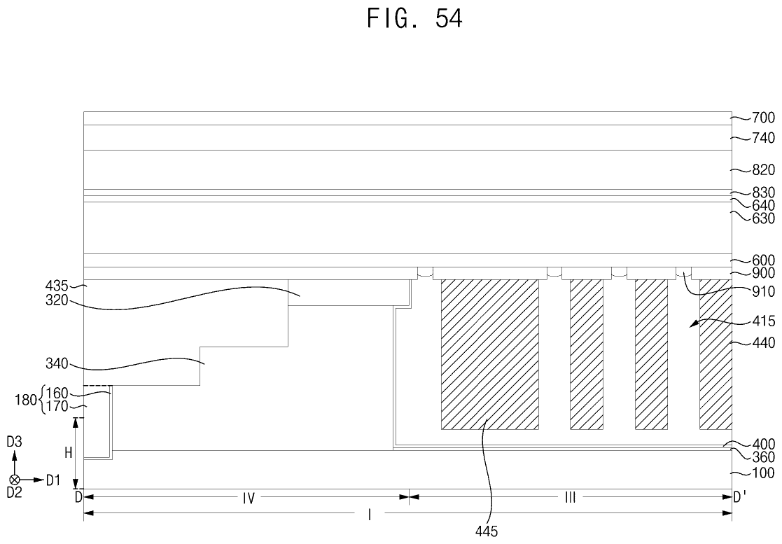

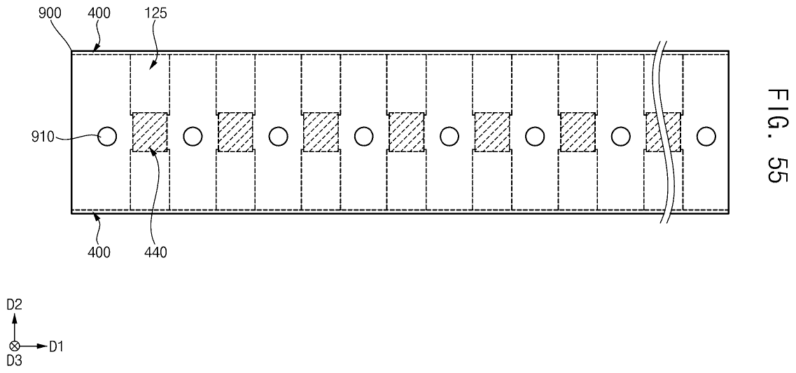

FIGS. 51 to 56 are horizontal cross-sectional views and vertical cross-sectional views illustrating a semiconductor device in accordance with example embodiments. Particularly, FIGS. 50-52, 55 and 56 are horizontal cross-sectional views taken through the seventh insulating interlayer 900, illustrating only key portions of the semiconductor device. FIGS. 53 and 54 are vertical cross-sectional views respectively taken along lines C-C′ and D-D′ of corresponding horizontal cross-sectional views. The semiconductor device may be substantially the same as or similar to that of FIGS. 47 to 50, except for the layout of the capping patterns 910.

Referring to FIG. 51, similar to the semiconductor device illustrated with reference to FIGS. 47 to 50, the capping pattern 910 may overlap in the third direction D3 the portions of the air spacer 415 located between neighboring ones of the channels 125 in the first direction D1.

However, unlike the semiconductor device illustrated with reference to FIGS. 47 to 50, in a plan view, one or more channels 125 may be disposed between neighboring ones of the capping patterns 910 in the first direction D1.

In FIG. 51, two channels 125 are shown to be disposed between neighboring ones of the capping patterns 910 in the first direction D1; however, the concept of the present invention is not limited thereto, and an arbitrary number of channels 125 may be disposed between neighboring ones of the capping patterns 910 in the first direction D1.

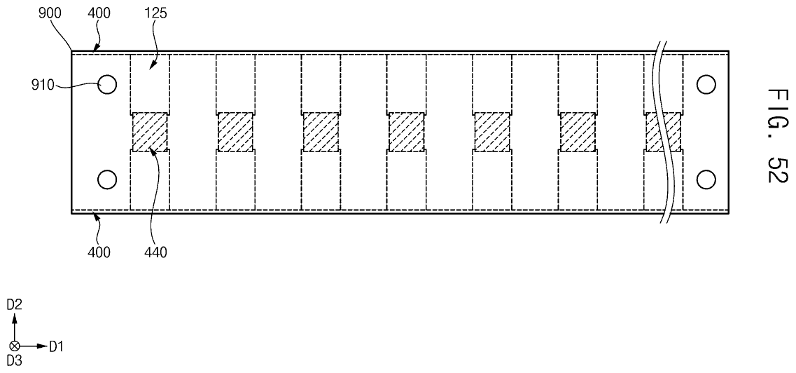

Referring to FIG. 52, the capping pattern 910 may overlap in the third direction D3 portions of the air spacer 415 adjacent to the channels 125 located at opposite ends in a first direction D1.

Referring to FIGS. 53 to 55, unlike the semiconductor device described with reference to FIGS. 47 to 50, the capping pattern 910 may overlap in the third direction D3 portions of the air spacer 415 located between neighboring ones of the bit lines 440 in the first direction D1.

In the drawing, one bit line 440 is shown to be disposed between neighboring ones of the capping patterns 910 in the first direction D1. That is, in a plan view, the capping pattern 910 and the bit line 440 may be arranged alternately and repeatedly along the first direction D1.

Alternatively, similar to the semiconductor device described with reference to FIG. 51, in a plan view, one or more bit lines 440 may be disposed between neighboring ones of the capping patterns 910 in the first direction D1.

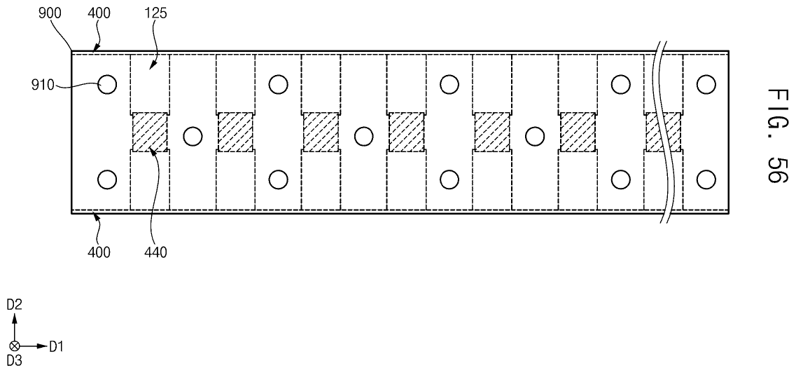

Referring to FIG. 56, some of the capping patterns 910 (hereinafter, first capping patterns) may overlap in the third direction D3 the portions of the air spacer 415 located between neighboring ones of the channels 125 in the first direction D1, and other ones of the capping patterns 910 (hereinafter, second capping patterns) may overlap in the third direction D3 the portions of the air spacer 415 located between neighboring ones of the bit lines 440 in the first direction D1.

In the drawing, although the first capping patterns and the second capping patterns are shown to be alternately and repeatedly arranged along the first direction D1, the concept of the present invention is not limited thereto.

Meanwhile, the layout of the capping patterns 910 may have various configurations and is not limited to those described with reference to FIGS. 50-52, 55 and 56.

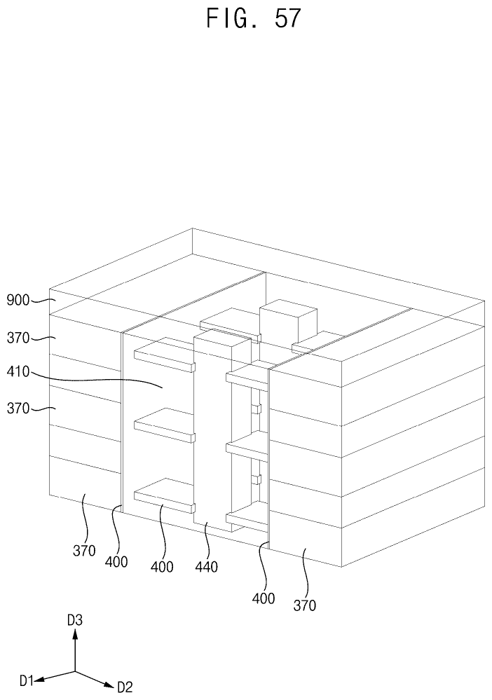

FIGS. 57 to 60 are perspective views illustrating a method of manufacturing a semiconductor device in accordance with example embodiments. The method of manufacturing the semiconductor device may be substantially the same or similar to those described with reference to FIGS. 1 to 46, and thus, repeated explanations are omitted herein.

Referring to FIG. 57, processes substantially the same as or similar to those described with reference to FIGS. 7 to 31 may be performed. Subsequently, a seventh insulating interlayer 900 may be formed on the second mask 320, the liner 400, and the sacrificial mold 410. The seventh insulating interlayer 900 may include an insulating nitride, e.g., silicon nitride.

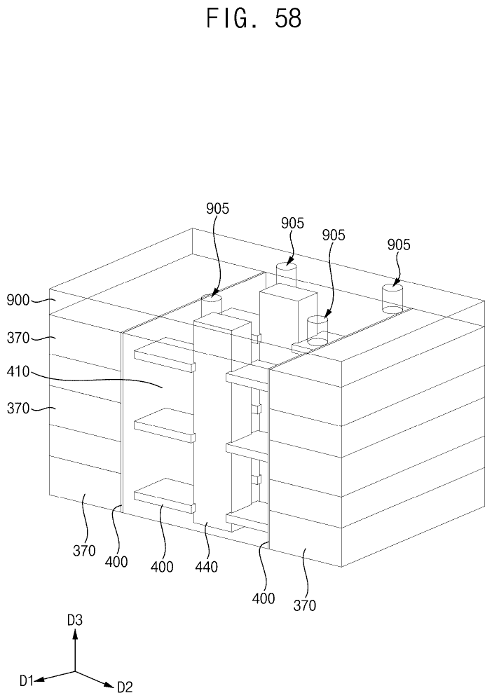

Referring to FIG. 58, a twelfth opening 905 may be formed to extend through the seventh insulating interlayer 900 to expose an upper surface of the sacrificial mold 410. In example embodiments, a plurality of twelfth openings 905 may be formed to be spaced apart from each other along the first and second directions D1 and D2.

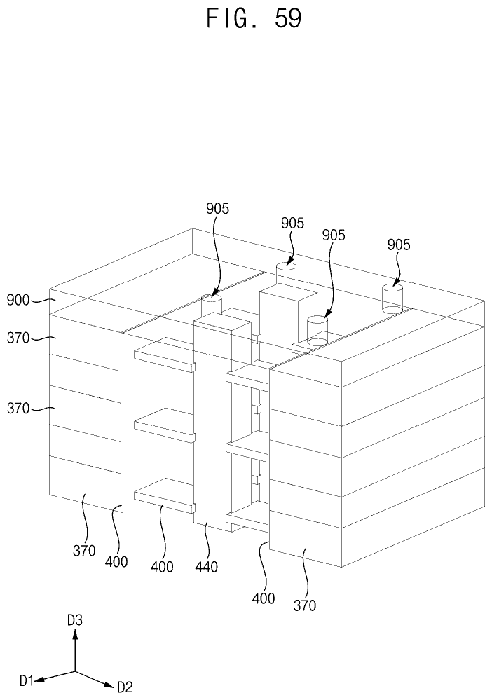

Referring to FIG. 59, the sacrificial mold 410 may be selectively removed by performing, for example, a wet etching process through the twelfth opening 905. In example embodiments, the wet etching process may be performed by a wet etching process using hydrofluoric acid (HF) as an etchant.

By removing the sacrificial mold 410, a surface of the liner 400 and a sidewall and a lower surface of the bit line 440 may be exposed, and a space may be formed between: the first extension portions of the channels 125 spaced apart from each other along the second and third directions D2 and D3, the bit lines 440 spaced apart from each other in the first direction D1, the dummy bit line 445 and the eighth division pattern 340 spaced apart from each other in the first direction D1, the lower surfaces of the bit lines 440 and the upper surface of the first substrate 100, and lower surfaces of the first extension portions of the channels 125 disposed at a lowermost layer and the upper surface of the first substrate 100

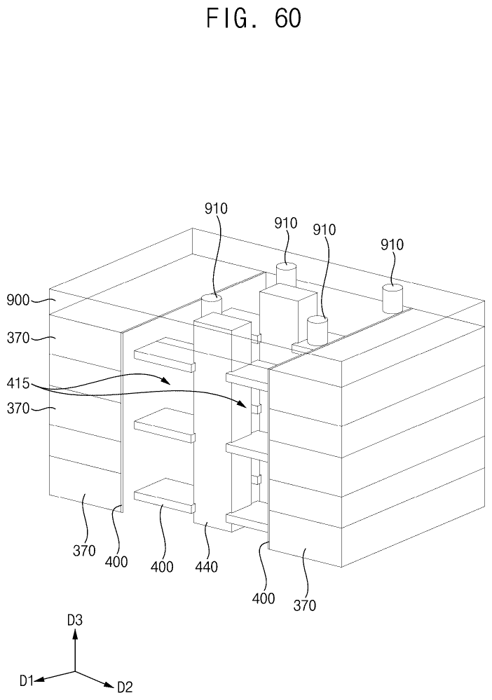

Referring to FIG. 60, a capping pattern 910 may be formed in the twelfth opening 905.

The capping pattern 910 may be formed using an insulating material having low gap-fill characteristics, and accordingly, the space therebelow may remain unfilled. The space formed by removing the sacrificial mold 410 may be referred to as an air spacer 415. The capping pattern 910 may include a material having low gap-fill characteristics, for example, silicon carbonitride (SiCN), silicon boronitride (SiBN), silicon oxycarbide (SiOC), silicon oxycarbonitride (SiOCN), silicon nitride (SiN), silicon oxide (SiO₂), etc.

In example embodiments, the capping pattern 910 may be formed to fill only an upper portion of the twelfth opening 905. Accordingly, a lower surface of the capping pattern 910 may be formed higher than a lower surface of the seventh insulating interlayer 900.

By performing processes substantially the same as or similar to those described with reference to FIGS. 45 and 46 and FIGS. 1 to 6, the manufacturing of the semiconductor device may be completed.

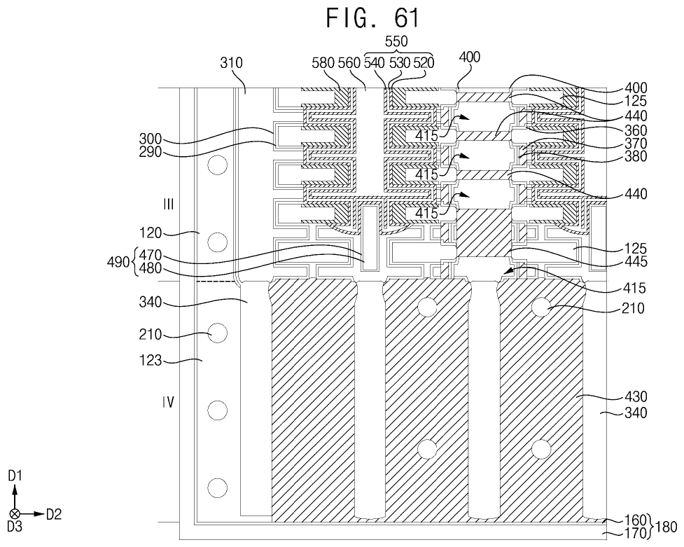

FIG. 61 is a horizontal cross-sectional view illustrating a semiconductor device in accordance with example embodiments. The semiconductor device may be substantially the same as or similar to that of FIGS. 1 to 6, except for the shape of the channel 125.

Referring to FIG. 61, a third width in the first direction D1 of the first extension portion of the channel 125 may decrease with decreasing distance from the bit line 440 in the second direction D2, and accordingly, the third width in the first direction D1 of the first extension portion of the channel 125 may be smaller than a fourth width in the first direction D1 of the center portion of the channel 125.

As the third width of the first extension portion of the channel 125 decreases, a distance in the first direction D1 between the contact portions of neighboring one of the channels 125 may increase. Accordingly, parasitic capacitance between neighboring ones of the channels 125 in the first direction D1 may decrease, thereby further improving reliability of the semiconductor device

FIGS. 57 to 60 are horizontal cross-sectional views illustrating a method of manufacturing a semiconductor device in accordance with example embodiments.

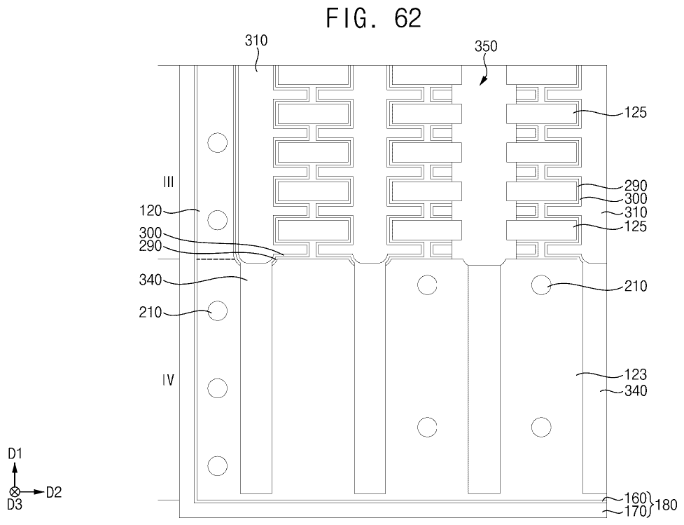

Referring to FIG. 62, after performing processes substantially the same as or similar to those described with reference to FIGS. 7 to 17, a seventh opening 350 may be formed by partially removing the second mask 320 and the third division structure through, for example, a dry etching process to expose an upper surface of the first substrate 100.

In example embodiments, the seventh opening 350 may expose upper and lower surfaces and sidewalls of the first extension portions of the channels 125.

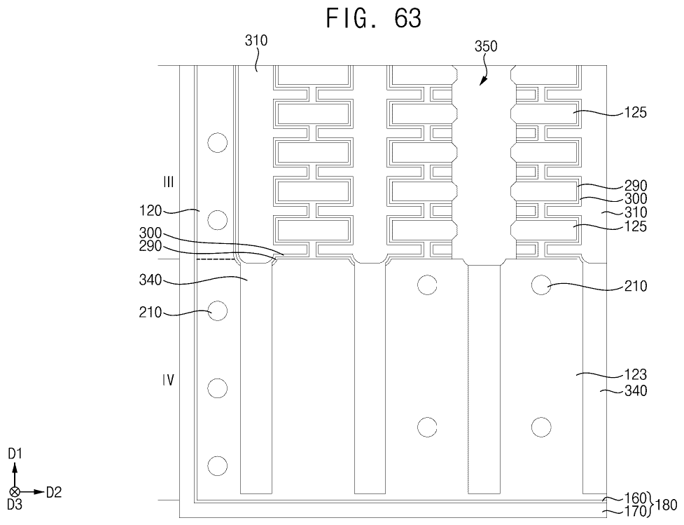

Referring to FIG. 63, the exposed first extension portions of the channels 125 may be subjected to, for example, a wet etching process. Accordingly, a width in the first direction D1 of the exposed first extension portion of the channel 125 may be formed to be smaller than a width in the first direction D1 of the unexposed center portion of the channel 125.

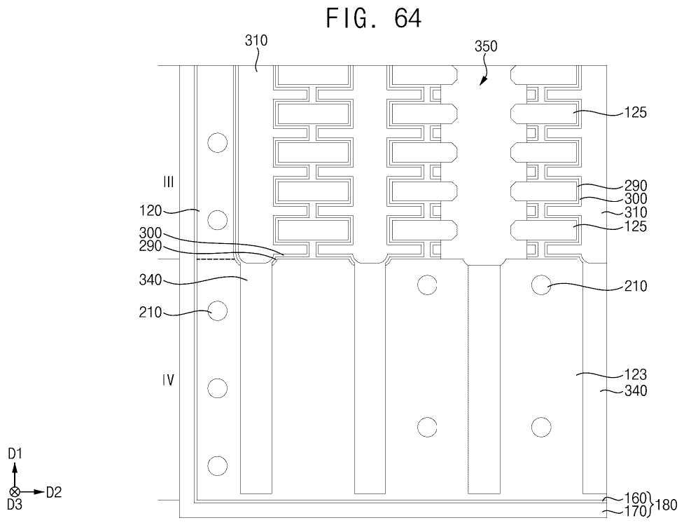

Referring to FIG. 64, the seventh opening 350 may be extended in the second direction D2 by further removing the third division structure through, for example, a dry etching process.

By performing processes substantially the same as or similar to those described with reference to FIGS. 20 to 46 and FIGS. 1 to 6. the manufacturing of the semiconductor device may be completed.

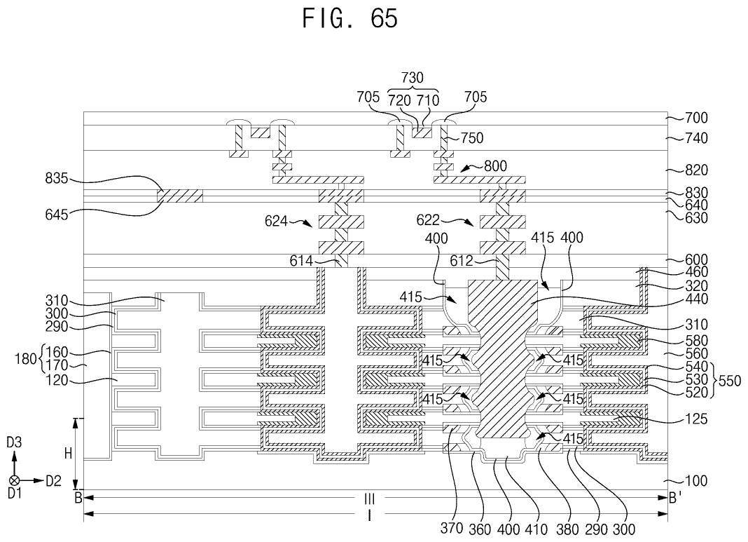

FIG. 65 is a vertical cross-sectional view illustrating a semiconductor device in accordance with example embodiments. The semiconductor device may be substantially the same as or similar to the semiconductor device described with reference to FIGS. 1 to 6, except for further including a sacrificial mold 410.

Referring to FIG. 65, the sacrificial mold 410 may be interposed between the lower surfaces of at least some of the bit lines 440 and the upper surface of the first substrate 100. This configuration may be formed when the sacrificial mold 410 disposed between the lower surface of at least some of the bit lines 440 and the upper surface of the first substrate 100 remains unremoved by the wet etching process during the processes described with reference to FIGS. 32 to 36.

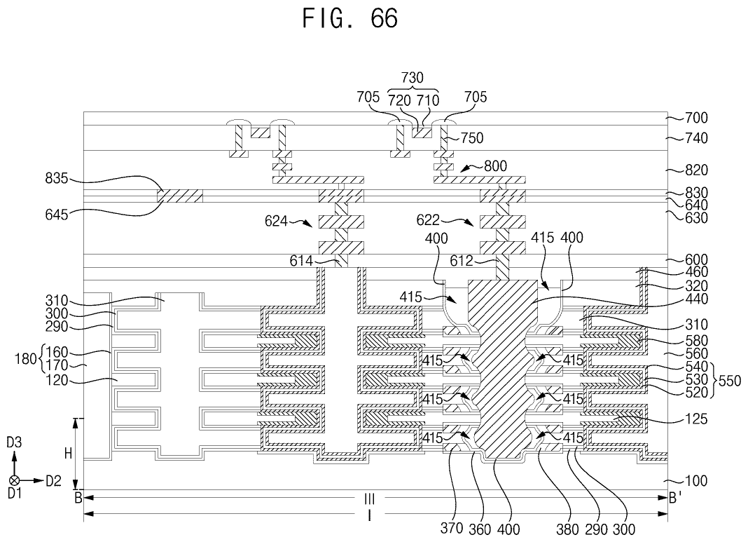

FIG. 66 is a vertical cross-sectional view illustrating a semiconductor device in accordance with example embodiments. The semiconductor device may be substantially the same as or similar to the semiconductor device described with reference to FIGS. 1 to 6, except for the shape of the bit line 440.

Referring to FIG. 66, the bit line 440 may extend through the air spacer 415 in the third direction D3 and may contact an upper surface of a portion of the liner 400 disposed on the upper surface of the first substrate 100. This configuration may be formed by performing the dry etching process such that the first trench exposes the upper surface of the liner 400 during the processes described with reference to FIGS. 29 to 31.

Each of FIGS. 65 and 66 may be formed to include the seventh insulating interlayer 900 and the capping pattern 910 extending therethrough instead of the capping layer 460, as illustrated in FIGS. 47 to 56.

While the inventive concept has been shown and described with reference to exemplary embodiments thereof, it will be apparent to those of ordinary skill in the art that various modifications in form and details may be made thereto without departing from the spirit and scope of the inventive concept as set forth by the following claims.

What is claimed is:

1. A semiconductor device, comprising:
a plurality of channels on a substrate and spaced apart from each other along a first direction substantially parallel to an upper surface of the substrate and a second direction substantially perpendicular to the upper surface of the substrate;
a plurality of gate structures, each extending in the first direction and at least partially surrounding portions of a first subset of the plurality of channels arranged in the first direction, and spaced apart from each other along the second direction;
a plurality of bit lines, each extending in the second direction and contacting sidewalls of a second subset of the plurality of channels arranged in the second direction, and spaced apart from each other along the first direction;
a capping layer on upper surfaces and upper sidewalls of the plurality of bit lines;
a capacitor electrically connected to the plurality of channels; and
an air spacer in a space between the plurality of channels, the plurality of gate structures, and the plurality of bit lines, and the space being between the upper surface of the substrate and a lower surface of the capping layer.

2. The semiconductor device of claim 1, wherein the capping layer comprises at least one of silicon carbonitride (SiCN), silicon boronitride (SiBN), silicon oxycarbide (SiOC), or silicon oxycarbonitride (SiOCN).

3. The semiconductor device of claim 1, further comprising a liner on the upper surface of the substrate and surfaces of the plurality of gate structures.

4. The semiconductor device of claim 3, wherein an upper surface of a portion of the liner on the upper surface of the substrate is spaced apart from lower surfaces of at least some of the plurality of bit lines.

5. The semiconductor device of claim 3, further comprising a sacrificial mold layer located between an upper surface of the liner on the upper surface of the substrate and at least some of the plurality of bit lines.

6. The semiconductor device of claim 5, wherein the sacrificial mold layer comprises a material having an etch selectivity with respect to the liner.

7. The semiconductor device of claim 3, wherein at least some of the plurality of bit lines contact an upper surface of the liner.

8. The semiconductor device of claim 1, wherein each of the plurality of channels extends in a third direction substantially parallel to the upper surface of the substrate and crossing the first direction,
wherein each of the plurality of channels includes a central portion and first and second extension portions, the first and second extension portions at opposite sides in the third direction of the central portion, the first extension portion contacting a sidewall of a corresponding one of the plurality of bit lines, and
wherein a width in the first direction of the first extension portion of each of the plurality of channels is smaller than a width in the first direction of the central portion of each of the plurality of channels.

9. A semiconductor device comprising:
a plurality of channels on a substrate, each extending in a first direction substantially parallel to an upper surface of the substrate, and spaced apart from each other along a second direction and a third direction, the second direction substantially parallel to the upper surface of the substrate and crossing the first direction and the third direction substantially perpendicular to the upper surface of the substrate;
a plurality of gate structures, each at least partially surrounding portions of a first subset of the plurality of channels arranged in the second direction, extending in the second direction, and spaced apart from each other in the third direction;
a plurality of bit lines, each contacting first sidewalls in the first direction of a second subset of the plurality of channels arranged along the third direction, each extending in the third direction, and spaced apart from each other in the second direction;
an insulating interlayer contacting upper surfaces of the plurality of bit lines;
capping patterns, each extending through the insulating interlayer, and spaced apart from each other in the second direction, wherein lower surfaces of the capping patterns are higher than a lower surface of the insulating interlayer and the upper surface of the substrate provides a base reference plane;
a capacitor electrically connected to second sidewalls in the first direction of the plurality of channels; and
an air spacer in a space between the plurality of channels, the plurality of gate structures and the plurality of bit lines, and the space being located between lower surfaces of the insulating interlayer and the capping patterns and the upper surface of the substrate.

10. The semiconductor device of claim 9, wherein each of the capping patterns comprises at least one of silicon carbonitride (SiCN), silicon boronitride (SiBN), silicon oxycarbide (SiOC), or silicon oxycarbonitride (SiOCN).

11. The semiconductor device of claim 9, wherein at least some of the capping patterns overlap in the third direction portions of the air spacer between neighboring ones of the plurality of channels in the second direction.

12. The semiconductor device of claim 9, wherein at least some of the capping patterns overlap in the third direction portions of the air spacer between neighboring ones of the plurality of bit lines in the second direction.

13. The semiconductor device of claim 9, further comprising a liner on the upper surface of the substrate and surfaces of the plurality of gate structures.

14. A semiconductor device comprising:
a plurality of channels on a substrate, each extending in a first direction substantially parallel to an upper surface of the substrate, and spaced apart from each other along a second direction and a third direction, the second direction substantially parallel to the upper surface of the substrate and crossing the first direction and the third direction substantially perpendicular to the upper surface of the substrate;
a plurality of gate structures, each at least partially surrounding portions of a subset of the plurality of channels arranged in the second direction, extending in the second direction, and spaced apart from each other in the third direction;
a division structure between neighboring ones of the plurality of gate structures in the third direction;
a plurality of bit lines, each contacting a first sidewall in the first direction of each of the plurality of channels arranged along the third direction, each extending in the third direction, and spaced apart from each other in the second direction;
a liner on the upper surface of the substrate, surfaces of the gate structures, and a sidewall of the division structure;
an insulating layer on upper surfaces of the bit lines and an uppermost surface of the liner;
a capacitor electrically connected to a second sidewall in the first direction of each of the plurality of channels; and
an air spacer in a space between a surface of the liner and a lower surface of the insulating layer.

15. The semiconductor device of claim 14, wherein the insulating layer contacts upper sidewalls of the plurality of bit lines.

16. The semiconductor device of claim 14, further comprising capping patterns each extending through the insulating layer and spaced apart from each other in the second direction,
wherein lower surfaces of the capping patterns are higher than a lower surface of the insulating layer and the upper surface of the substrate provides a base reference plane.

17. The semiconductor device of claim 14, wherein an upper surface of the liner on the upper surface of the substrate is spaced apart from lower surfaces of at least some of the bit lines.

18. The semiconductor device of claim 14, further comprising a mold layer between an upper surface of the liner on the upper surface of the substrate and at least some of the plurality of bit lines.

19. The semiconductor device of claim 14, wherein at least some of the plurality of bit lines contact an upper surface of the liner on the upper surface of the substrate.

20. The semiconductor device of claim 14, wherein each of the plurality of channels includes a central portion and first and second extension portions, the first and second extension portions on sides in the first direction of the central portion, the first extension portion contacting a sidewall of a corresponding one of the plurality of bit lines, and
wherein a width in the second direction of the first extension portion of each of the plurality of channels is smaller than a width in the second direction of the central portion of each of the plurality of channels.
